(19) United States
(12) Patent Application Publication
(10) Pub. No.: US 2026/0006893 A1
(43) Pub. Date: Jan. 1, 2026

(54) SEMICONDUCTOR DEVICE AND POWER CONVERSION DEVICE

(71) Applicant: Mitsubishi Electric Corporation, Tokyo (JP)

(72) Inventors: Shiro HINO, Tokyo (JP); Akifumi IIJIMA, Tokyo (JP); Kotaro KAWAHARA, Tokyo (JP); Katsutoshi SUGAWARA, Tokyo (JP); Katsuhiro FUJIYOSHI, Tokyo (JP)

(73) Assignee: Mitsubishi Electric Corporation, Tokyo (JP)

(21) Appl. No.: 18/878,495

(22) PCT Filed: Aug. 3, 2022
(86) PCT No.: PCT/JP2022/029727

§ 371 Date: Dec. 23, 2024

(51) Int. Cl. H10D 84/00; H02M 7/162; H10D 8/00; H10D 8/01; H10D 8/60; H10D 30/01; H10D 30/66; H10D 62/10; H10D 62/60; H10D 62/832

(52) U.S. Cl. CPC H10D 84/146; H02M 7/1623; H10D 8/411; H10D 8/60; H10D 30/665; H10D 30/668; H10D 62/126; H10D 62/60; H10D 84/143; H10D 8/045; H10D 8/051; H10D 30/0291; H10D 30/0295; H10D 30/0297; H10D 62/8325

(57) ABSTRACT

A semiconductor device and a power conversion device each comprise a drift layer, a gate electrode to face a well region and a source region via a gate insulating film, a source electrode provided on an interlayer insulating film covering the gate electrode and connected to the well region and the source region, a first separation region provided in an active region in which a plurality of MOSFETs each including the well region, the source region, and the gate electrode are arranged in the drift layer, the first separation region being provided to be connected to the drift layer and forming Schottky connection with the source electrode, and a surge current conduction region provided in the active region, and blocks connection between the source electrode and the drift layer, thereby enabling the achievement of a semiconductor device and a power conversion device that exhibit high surge tolerance.

### TECHNICAL FIELD

The present disclosure particularly relates to a semiconductor device made of silicon carbide and a power conversion device using the semiconductor device.

### BACKGROUND ART

There is a semiconductor device in which a metal oxide semiconductor field effect transistor (MOSFET) region and a Schottky barrier diode (SBD) region are both formed in an active region. In such a semiconductor device, for example, as disclosed in Patent Document 1, a structure is disclosed in which a Schottky junction forming region formed of a junction between an n-type semiconductor and a metal electrode is subdivided by a regular p-type implantation region, thereby reducing a Schottky junction electric field and reducing a leakage current.

### Prior Art Document

### Patent Document

Patent Document 1 Japanese Publication of Unexamined Application No. 2020-161841 (FIG. 6)

### SUMMARY OF INVENTION

### Problems to be Solved by Invention

In the semiconductor device as described above, when a large current, called a surge current, flows through the SBD, the SBD generates heat due to a large resistance of the SBD, which originates from the conduction principle of the SBD, and the gate oxide film may be broken. Thus, it is difficult to obtain a semiconductor device and a power conversion device having high surge tolerance.

The present disclosure has been made to solve the above-described problem, and an object of the present disclosure is to provide a semiconductor device and a power conversion device that suppress a gate oxide film from being broken due to a surge current flowing in the semiconductor device and have high surge tolerance.

### Means for Solving Problems

A semiconductor device according to the present disclosure includes a drift layer of a first conductivity type, a gate electrode provided so as to face a well region of a second conductivity type and a source region of the first conductivity type via a gate insulating film, a source electrode that is provided on an interlayer insulating film provided so as to cover the gate electrode and that is connected to the well region and the source region, a first separation region of the first conductivity type provided in an active region in which a plurality of MOSFETs each including the well region, the source region, and the gate electrode are arranged in the drift layer, the first separation region being provided to be connected to the drift layer and forming Schottky connection with the source electrode, and a surge current conduction region provided in the active region, formed over a region larger than a first width of the well region in a plan view, and having a region for blocking connection between the source electrode and the drift layer.

Further, a power conversion device according to the present disclosure includes a main conversion circuit that includes the semiconductor device according to the present disclosure and converts input power and outputs the converted power, and a control circuit that outputs a control signal for controlling the main conversion circuit.

### Effects of Invention

According to the present disclosure, it is possible to suppress a gate oxide film from being broken due to a surge current flowing through a semiconductor device, and to obtain a semiconductor device and a power conversion device having high surge tolerance.

### BRIEF DESCRIPTION OF DRAWINGS

FIG. 1 is a schematic plan view showing a schematic configuration of a semiconductor device according to Embodiment 1.

FIG. 2 is a schematic plan view showing a schematic configuration of the semiconductor device according to Embodiment 1.

FIG. 3 is a schematic cross-sectional view showing a schematic configuration of the semiconductor device according to Embodiment 1.

FIG. 4 is a schematic cross-sectional view showing a schematic configuration of the semiconductor device according to Embodiment 1.

FIG. 5 is a schematic plan view showing a schematic configuration of the semiconductor device according to Embodiment 1.

FIG. 6 is a schematic cross-sectional view showing a schematic configuration of the semiconductor device according to Embodiment 1.

FIG. 7 is a schematic cross-sectional view showing a schematic configuration of the semiconductor device according to Embodiment 1.

FIG. 8 is an explanatory view of a method of manufacturing the semiconductor device according to Embodiment 1.

FIG. 9 is an explanatory view of the method of manufacturing the semiconductor device according to Embodiment 1.

FIG. 10 is an explanatory view of the method of manufacturing the semiconductor device according to Embodiment 1.

FIG. 11 is an explanatory view of the method of manufacturing the semiconductor device according to Embodiment 1.

FIG. 12 is an explanatory view of a method of manufacturing the semiconductor device according to Embodiment 1.

FIG. 13 is an explanatory view of the method of manufacturing the semiconductor device according to Embodiment 1.

FIG. 14 is an explanatory view of the method of manufacturing the semiconductor device according to Embodiment 1.

FIG. 15 is an explanatory view of the method of manufacturing the semiconductor device according to Embodiment 1.

FIG. 16 is a schematic plan view showing a schematic configuration of the semiconductor device according to Embodiment 1.

FIG. 17 is a schematic plan view showing a schematic configuration of the semiconductor device according to Embodiment 1.

FIG. 18 is a schematic cross-sectional view showing a schematic configuration of a semiconductor device according to Embodiment 2.

FIG. 19 is a schematic cross-sectional view showing a schematic configuration of a semiconductor device according to Embodiment 3.

FIG. 20 is a schematic cross-sectional view showing a schematic configuration of a semiconductor device according to Embodiment 4.

FIG. 21 is a schematic plan view showing a schematic configuration of a semiconductor device according to Embodiment 5.

FIG. 22 is a schematic plan view showing a schematic configuration of the semiconductor device according to a Embodiment 5.

FIG. 23 is a schematic cross-sectional view showing a schematic configuration of the semiconductor device according to Embodiment 5.

FIG. 24 is a schematic cross-sectional view showing a schematic configuration of the semiconductor device according to Embodiment 5.

FIG. 25 is an explanatory view of a method of manufacturing the semiconductor device according to Embodiment 5.

FIG. 26 is an explanatory view of a method of manufacturing the semiconductor device according to Embodiment 5.

FIG. 27 is an explanatory view of a method of manufacturing the semiconductor device according to Embodiment 5.

FIG. 28 is an explanatory view of a method of manufacturing the semiconductor device according to Embodiment 5.

FIG. 29 is an explanatory view of a method of manufacturing the semiconductor device according to Embodiment 5.

FIG. 30 is an explanatory view of a method of manufacturing the semiconductor device according to Embodiment 5.

FIG. 31 is a schematic diagram showing a schematic configuration of a power conversion system to which a power conversion device according to Embodiment 6 is applied.

### EMBODIMENTS FOR CARRYING OUT THE INVENTION

In the following description, an n-type and a p-type indicate the conductivity type of a semiconductor, and in the present disclosure, a first conductivity type is described as the n-type and a second conductivity type is described as the p-type, but the first conductivity type may be the p-type and the second conductivity type may be the n-type. Further, an n-type indicates that the impurity concentration is lower than the impurity concentration of the n type, and an n+ type indicates that the impurity concentration is higher than the impurity concentration of the n type. Similarly, a p-type indicates that the impurity concentration is lower than the impurity concentration of the p type, and a p+ type indicates that the impurity concentration is higher than the impurity concentration of the p type. Unless otherwise specified, a pn junction and a pn diode may be used in the same meaning, and application of a voltage equal to or higher than a threshold voltage to a pn diode may be expressed as “a pn diode is turned on”, “a pn junction is turned on”, or the like. In addition, application of a voltage higher than or equal to a threshold voltage to a gate electrode may be expressed as “a gate is turned on”, for example.

Hereinafter, embodiments will be described with reference to the accompanying drawings. Note that the drawings are schematic, and the size and positional relation of an image shown in each of different drawings are not necessarily accurate and can be changed as appropriate. In the following description, the same components are denoted by the same reference numerals, and the names and functions thereof are also the same, and thus detailed description thereof may be omitted.

### Embodiment 1

The semiconductor device according to the present embodiment will be described below. First, a structure of a semiconductor device will be described.

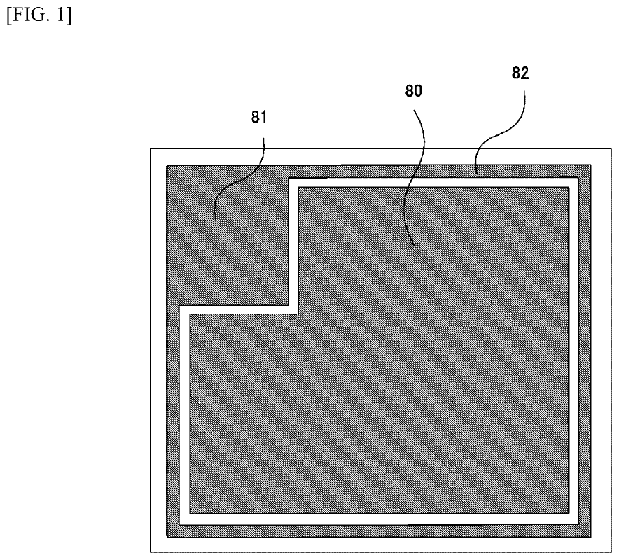

FIG. 1 is a schematic plan view showing a schematic configuration of a semiconductor device according to Embodiment 1. Here, FIG. 1 corresponds to a view of a SiC-MOSFET with a built-in SBD as viewed from the upper surface side thereof. In FIG. 1, a gate pad 81 is formed on a part of the upper surface of the SiC-MOSFET with the built-in SBD, and a source electrode 80 is formed adjacent to the gate pad 81. A gate wire 82 is formed so as to extend from the gate pad 81.

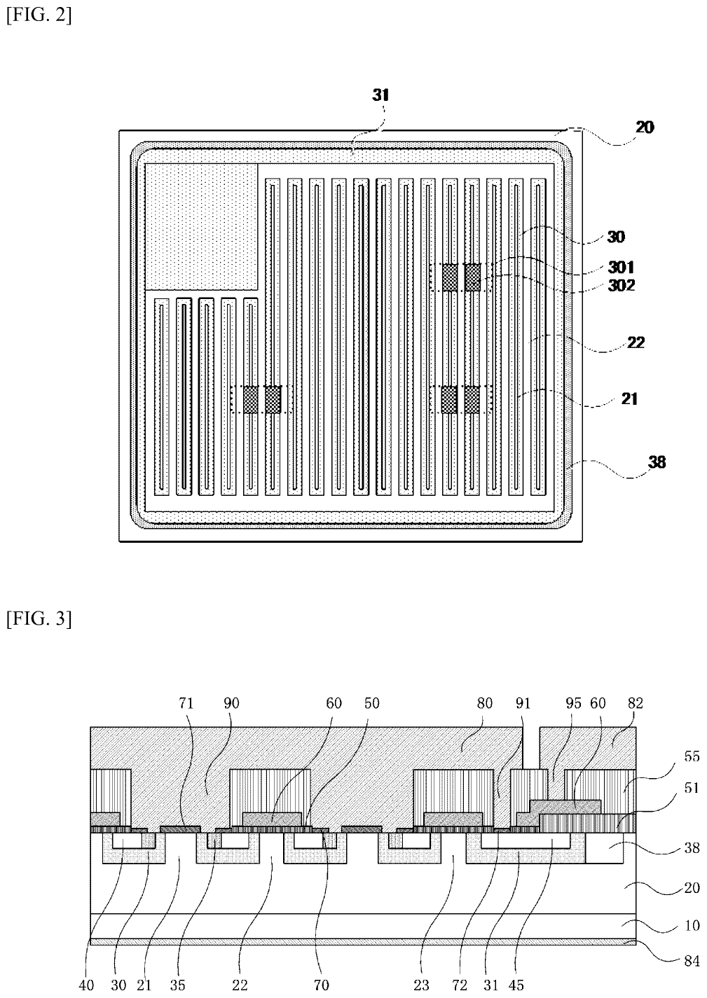

FIG. 2 is a schematic plan view showing a schematic configuration of the semiconductor device according to Embodiment 1. Here, FIG. 2 corresponds to a figure in which electrode layers such as the source electrode 80 are seen through in FIG. 1 and semiconductor layers are mainly shown, and shows an example in which three surge current conduction regions 301 are provided. The semiconductor device shown in FIG. 2 is a device in which unit cell regions in each of which the MOSFET region is formed on both sides across an SBD region are arranged in a stripe shape, and is referred to as a “stripe type”. Hereinafter, a stripe-type semiconductor device will be described.

In FIG. 2, the unit cell region including an n-type first separation region 21 substantially corresponding to the SBD and a p-type first well region 30 substantially corresponding to the MOSFET is repeatedly arranged in one direction in a plan view. A region where a plurality of MOSFETs with the built-in SBDs are formed is referred to as an active region together with the surge current conduction region 301 to be described later, and a region including a forming region of the gate pad 81 where a p-type second well region 31 and the like are formed, which is formed on the outer periphery of the active region, is referred to as a termination region.

FIG. 3 is a schematic cross-sectional view showing a schematic configuration of the semiconductor device according to Embodiment 1. FIG. 3 shows a cross section in a direction orthogonal to a stripe longitudinal direction, from the source electrode 80 to the gate wire 82 of the outer periphery of the semiconductor device in FIG. 1.

In FIG. 3, a drift layer 20 made of n-type silicon carbide is formed on the surface of a semiconductor substrate 10 made of n-type silicon carbide having low resistance. As shown in the cross-sectional view of FIG. 3, the second well region 31 made of p-type silicon carbide is provided in a surface layer portion of the drift layer 20 at a position including the region where the gate wire 82 described in FIG. 1 is provided.

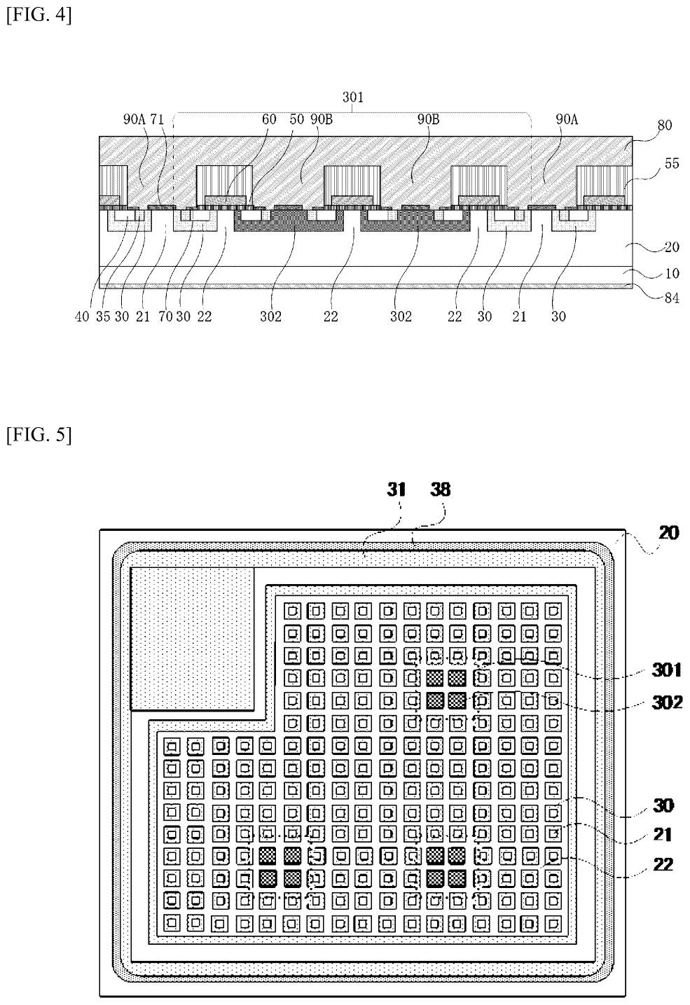

FIG. 4 is a schematic cross-sectional view showing a schematic configuration of the semiconductor device according to Embodiment 1. Here, FIG. 4 shows a cross section in the direction orthogonal to the stripe longitudinal direction, including the surge current conduction region 301 of FIG. 2.

In FIG. 4, an auxiliary region 302 made of p-type silicon carbide and formed in a surface layer portion of the drift layer 20 is formed in the surge current conduction region 301. The auxiliary region 302 is located between a Schottky electrode 71 and the drift layer 20, and forms a pn junction with the drift layer 20 in a conduction path from the source electrode 80 to a drain electrode 84. This prevents the Schottky electrode 71 from being connected to the n-type silicon carbide in this region. The term “connected” means a state in which the pn junction is not interposed in the conduction path and a Schottky current can flow in the vertical direction or the horizontal direction in the cross section of the semiconductor device.

In the active region that is a lower portion in the region where the source electrode 80 described in FIG. 1 is provided, the first well region 30 formed in a stripe shape and made of p-type silicon carbide is provided in the surface layer portion of the drift layer 20. The first well regions 30 may be connected to each other, or a plurality of separated first well regions 30 may be provided.

In the surface layer portion of each of the first well regions 30, a source region 40 made of n-type silicon carbide is formed at a position inside from the outer periphery of the first well region 30 by a predetermined distance.

In the surface layer portion of each first well region 30, a contact region 35 made of p-type silicon carbide having low resistance is formed further inside the source region 40, and a first separation region 21 made of silicon carbide and having a stripe shape in a plan view is formed further inside the contact region 35 so as to penetrate the first well region 30. The first separation region 21 is of the same n-type as the drift layer 20, and the n-type impurity concentration of the first separation region 21 may be the same as the n-type impurity concentration of the drift layer 20, or may be higher or lower than the n-type impurity concentration of the drift layer 20.

On the front surface side of the first separation region 21, the Schottky electrode 71 is formed in a stripe shape in a plan view, which forms a Schottky connection to the first separation region 21. Here, the Schottky electrode 71 is preferably formed so as to include at least the corresponding first separation region 21 when viewed from the upper surface.

An ohmic electrode 70 is formed on the surface of the source region 40 and the 20) contact region 35, and the source electrode 80 connected to the ohmic electrode 70, the Schottky electrode 71, and the contact region 35 is formed thereon. The first well region 30 can easily exchange electrons and holes with the ohmic electrode 70 via the low-resistance contact region 35.

A region of the drift layer 20 between the adjacent first well regions 30 is an n-type second separation region 22. The n-type impurity concentration of the second separation region 22 may be the same as the n-type impurity concentration of the drift layer 20, or may be higher or lower than the n-type impurity concentration of the drift layer 20. A gate insulating film 50 made of silicon oxide is formed on the surfaces of the adjacent first well regions 30, the second separation region 22 therebetween, and the source region 40 in each of the first well regions 30, and a gate electrode 60 made of polycrystalline silicon is formed on the gate insulating film 50 at least above the first well regions 30. The surface layer portion of the first well region 30 facing the gate electrode 60 via the gate insulating film 50 is referred to as a channel region.

The second well region 31 is formed outside the first well region 30 of the outermost periphery of the semiconductor device, and a third separation region 23 is formed between the first well region 30 and the second well region 31. The third separation region 23 is of the same n-type as the drift layer 20, and the n-type impurity concentration of the third separation region 23 may be the same as the n-type impurity concentration of the drift layer 20 or may be higher or lower than the n-type impurity concentration of the drift layer 20. Further, the gate insulating film 50 is formed also on the second well region 31, and a gate electrode 60 electrically connected to the gate electrode 60 formed on the first well region 30 is formed on the gate insulating film 50.

A silicon carbide conductive layer 45 made of silicon carbide, which is of an n-type and has a lower resistance and a higher impurity concentration than the drift layer 20, is formed in a region of a certain proportion of the upper layer portion of the second well region 31. The silicon carbide conductive layer 45 has a sheet resistance lower than that of the second well region 31, and forms a pn junction with the p-type second well region 31. In addition, the silicon carbide conductive layer 45 is formed in the second well region 31 over a width of half or more of the width of the second well region 31 in the lateral direction of the cross section. The portion where the silicon carbide conductive layer 45 is formed with a width of half or more of the width of the second well region 31 in the lateral direction of the cross section does not need to be the entire cross sections, and may be only a part of the cross sections.

An interlayer insulating film 55 made of silicon oxide is formed between the gate electrode 60 and the source electrode 80. Further, the gate electrode 60 above the second well region 31 and the gate wire 82 are connected to each other via a gate contact hole 95 formed in the interlayer insulating film 55. Further, a p-type silicon carbide junction termination extension (JTE) region 38 is formed on the outer peripheral side of the second well region 31, that is, on the side opposite to the first well region 30. The impurity concentration of the JTE region 38 is lower than the impurity concentration of the second well region 31. A field limiting ring (FLR) may be formed instead of the JTE region 38. Alternatively, a combination of the JTE region 38 and the FLR may be used.

A field insulating film 51 having a larger film thickness than that of the gate insulating film 50, or the gate insulating film 50 is formed on the second well region 31 and the silicon carbide conductive layer 45. An opening, that is, a termination region contact hole 91 is formed in a part of the gate insulating film 50 or the field insulating film 51 on the surface of the silicon carbide conductive layer 45, and the silicon carbide conductive layer 45 is ohmically connected to the source electrode 80 formed thereon via a termination portion ohmic electrode 72 through the opening.

The termination region contact hole 91 penetrates the field insulating film 51 and the interlayer insulating film 55, and allows ohmic connection between the silicon carbide conductive layer 45 and the source electrode 80. The silicon carbide conductive layer 45 and the second well region 31 are not ohmically connected. In addition, the silicon carbide conductive layer 45 has a width larger than the diameter of the termination region contact hole 91. Here, the second well region 31 is not directly ohmically connected to the source electrode 80.

In the active region, the ohmic electrode 70, the Schottky electrode 71, and the contact region 35 are connected to the source electrode 80 via an active region contact hole 90 that is formed by penetrating the interlayer insulating film 55 and the gate insulating film 50. The active region contact hole 90 includes an active region first contact hole 90A formed outside the surge current conduction region 301 and at an end portion of the surge current conduction region 301, and an active region second contact hole 90B formed to face the auxiliary region 302 of the surge current conduction region 301. The drain electrode 84 is formed on the rear surface side of the semiconductor substrate 10.

When the plane orientation of the first main surface of the semiconductor substrate 10 is a (0001) plane having an off angle in a <11-20> direction, the stripe-shaped first well region 30 may be formed in parallel to the <11-20> direction or may be formed in parallel to a direction orthogonal to the off direction.

The surge current conduction region 301, which is a feature of the present disclosure, is provided in the active region, is formed over a region larger than the first width of the first well region 30 in a plan view, and has a region that blocks the connection between the source electrode 80 and the drift layer 20. That is, the length of the surge current conduction region 301 in both the longitudinal direction and the lateral direction is larger than the first width being the width in a shorter side among the widths of the first well region 30. In addition, the surge current conduction region 301 has a sufficiently small area with respect to the entire active region and is covered with the source electrode 80 in a plan view. From these points, the second well region 31 having a large area, which is formed below the gate pad 81 around the active region and also formed in a region not covered by the source electrode 80, and the surge current conduction region 301 can be clearly distinguished.

The surge current conduction region 301 can be defined as a region in which the first separation region 21 in contact with the Schottky electrode 71 is not formed and which is interposed between the first separation regions 21. Here, the term “interposed” refers to a case where the first separation region 21 is adjacent to the entire periphery of the surge current conduction region 301 in a plan view, and a case where a plurality of the first separation regions 21 are periodically arranged at the end portions in the stripe direction, that is, the surge current conduction region 301 has portions adjacent to the first separation regions 21 and portions not adjacent thereto, as shown in FIG. 2.

The separation distance between the two first separation regions 21 provided each adjacent on one end side and the other end side of the surge current conduction region 301 is larger than the separation distance between the two first separation regions 21 adjacent to each other in the active region outside the surge current conduction region 301. Here, it can be said that the separation distance between the two first separation regions 21 provided each adjacent on one end side and the other end side of the surge current conduction region 301 corresponds to or substantially corresponds to the width of the surge current conduction region 301 in the lateral direction in FIG. 2 and FIG. 4.

When one surge current conduction region 301 is formed in the active region, the position where the surge current conduction region 301 is disposed is not limited, but the surge current conduction region 301 can be disposed in the central region of the active region such that the distance from the termination region to the surge current conduction region 301 is about one fourth of the length of the semiconductor device in the longitudinal direction or the lateral direction in a plan view. With this configuration, when a surge current flows through the semiconductor device, heat generated by the surge current can be widely dispersed over the entire semiconductor device.

In addition, when two or more surge current conduction regions 301 are formed in the active region, the positions where the surge current conduction regions 301 are disposed are not limited, but it is preferable that the surge current conduction regions 301 are evenly arranged over the entire semiconductor device in a plan view, that is, the surge current conduction regions 301 are formed so as to be provided periodically or at equal intervals in at least one direction of the semiconductor device in a plan view. In this way, when a surge current flows through the semiconductor device, the surge current easily flows uniformly in the plane of the semiconductor device, and damage or destruction of the structure of the gate insulating film 50 and the like is suppressed.

The auxiliary region 302 may be formed in the surge current conduction region 301, and a hole filling auxiliary region 303 to be described later may be formed. FIG. 4 shows an example in which two auxiliary regions 302 are formed. The auxiliary region 302 is a region that exhibits the second conductivity type and blocks the connection between the source electrode 80 and the drift layer 20, and has the second width larger than the first width of the first well region 30.

In the present embodiment, the auxiliary region 302 is a region in which the n-type first separation region 21 replaced with a p-type layer and two first well regions 30 are combined. The auxiliary region 302 is formed to cover the active region second contact hole 90B that is periodically formed, that is, to be larger than the diameter of the active region second contact hole 90B. In such a layout, the width of the auxiliary region 302 is inevitably larger than the width of the first well region 30. Two advantages of this layout will be described below.

First, in the surge current conduction region 301, the gate electrodes 60 and the active region contact holes 90 can be formed at the same pitch as in the surrounding region. In this way, in the semiconductor device, the gate electrodes 60 and the active region contact holes 90 can be arranged at equal intervals, and the uniformity in the processing can be improved. Further, at the end portion of the surge current conduction region 301 in the stripe direction, it is not necessary to discontinue or branch the gate electrodes 60 and the active region contact holes 90, and the uniformity in the processing can be further improved.

Next, the gate electrode 60 is configured to run through the surge current conduction region 301, that is, the gate electrode 60 is continuously formed inside and outside the surge current conduction region 301 in a plan view. In this way, when the gate potential propagates in the gate electrode 60, the propagation of the gate potential can be prevented from being interrupted even in the surge current conduction region 301, and particularly in the stripe-type semiconductor device, the region where the MOSFET functions, that is, can be effectively utilized, can be increased. In addition, when the gate electrode 60 is configured to run through the surge current conduction region 301, the delay in the propagation of the gate potential is smaller than when the gate electrode 60 is formed to bypass the surge current conduction region 301, and therefore, high-speed switching can be achieved, and the switching current can be suppressed from concentrating locally in the semiconductor device. Note that the gate electrode 60 may not be provided in the surge current conduction region 301 in a plan view.

In the active region first contact hole 90A penetrating the interlayer insulating film 55, the source electrode 80 is connected to the first well region 30, the source region 40, the first separation region 21, and the Schottky electrode 71 via the active region first contact hole 90A. In the active region second contact hole 90B penetrating the interlayer insulating film 55, the source electrode 80 is connected to the auxiliary region 302 and the Schottky electrode 71 via the active region second contact hole 90B and is not connected to the drift layer 20. That is, the auxiliary region 302 isolates the source electrode 80 and the drift layer 20 from each other in the active region second contact hole 90B penetrating the interlayer insulating film 55. Here, in the portion between the Schottky electrode 71 and the drift layer 20, a pn diode formed with a junction between the auxiliary region 302 and the drift layer 20 is interposed, and the Schottky electrode 71 and the drift layer 20 are isolated from each other at the portion and do not have the Schottky junction.

As another feature of the present embodiment, the surge current conduction region 301 includes the second separation region 22 of the first conductivity type that is adjacent to the auxiliary region 302 or the first well region 30, is connected to the drift layer 20, faces the gate electrode 60 via the gate insulating film 50, and is adjacent to the channel region. In FIG. 4, the surge current conduction region 301 includes the second 30 separation regions 22 interposed between two adjacent auxiliary regions 302 and between the auxiliary region 302 and the first well region 30. Here, the source region 40 is provided in the surface layer of the auxiliary region 302, and the gate insulating film 50 and the gate electrode 60 are formed on a region ranging from the second separation region 22 to the source region 40. That is, a channel structure is formed in the auxiliary region 302 in the same manner as the channel structure formed in the active region other than the surge current conduction region 301.

A separation distance between the source region 40 and the second separation region 22 in the channel structure is referred to as a channel length. The channel length in the auxiliary region 302 is preferably set to be equal to the channel length in the active region other than the surge current conduction region 301. If the channel length in the auxiliary region 302 is extremely shortened, a current starts to flow in the channel even at a low gate voltage due to a short channel effect, the threshold voltage of the entire semiconductor device is lowered, and the semiconductor device is likely to malfunction. In contrast, if the channel length in the auxiliary region 302 is extremely long, the current flowing through the channel is reduced, and it is difficult to obtain an effect to be described later.

For the same reason, the impurity concentration in the channel portion of the auxiliary region 302 is preferably equal to the impurity concentration in the channel portion of the active region other than the surge current conduction region 301. In addition, the thickness of the gate insulating film 50 in the channel structure of the auxiliary region 302 is preferably equal to the thickness of the gate insulating film 50 in the active region other than the surge current conduction region 301. This can suppress a decrease in the gate dielectric strength and a decrease in the channel current.

The above is the description of the stripe-type semiconductor device.

FIG. 5 is a schematic cross-sectional view showing a schematic configuration of a semiconductor device according to Embodiment 1. The semiconductor device of FIG. 5 has a configuration different from that of the SiC-MOSFET with the built-in SBD in the stripe type shown in FIG. 2. The semiconductor device is a device in which a unit cell region in which the MOSFET region surrounding the SBD region is formed is repeatedly arranged in a matrix in a plan view, and is referred to as a “lattice type”. A lattice-type semiconductor device will be described below.

In FIG. 5, the unit cell region including the n-type first separation region 21 substantially corresponding to the SBD and the p-type first well region 30 substantially corresponding to the MOSFET is repeatedly arranged in the vertical and horizontal directions in a plan view. A region combining the region where the MOSFET with the built-in SBD is formed and the surge current conduction region 301 is referred to as the active region, and a region including the forming region of the gate pad 81 where the p-type second well region 31 and the like are formed, which is formed on the outer periphery 30 of the active region, is referred to as the termination region.

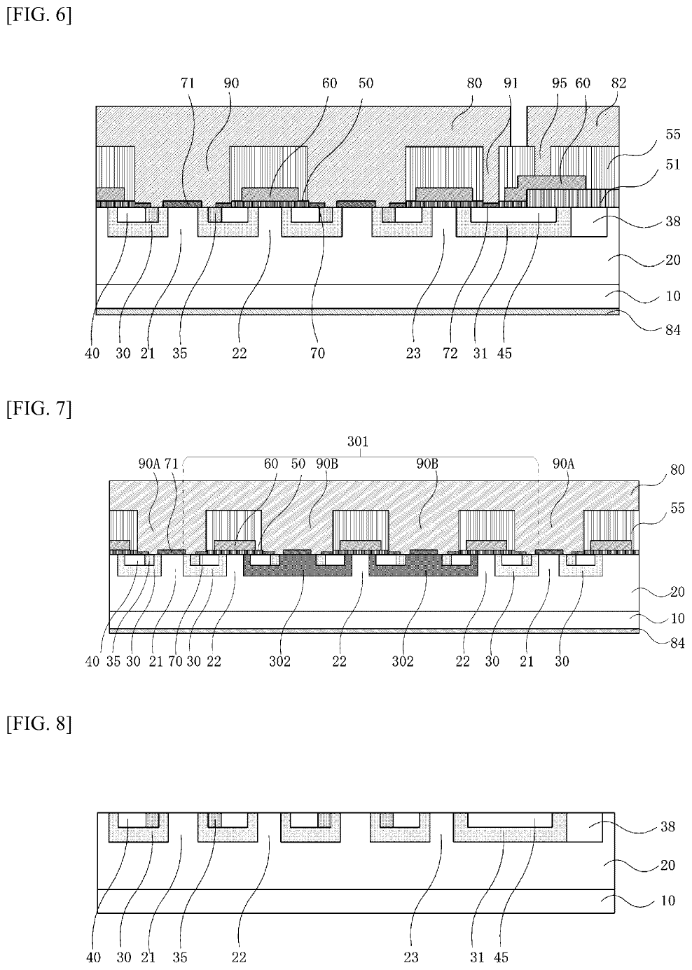

FIG. 6 is a schematic cross-sectional view showing a schematic configuration of the semiconductor device according to Embodiment 1. FIG. 3 shows a certain cross section from the source electrode 80 to the gate wire 82 that is provided on the outer periphery of the semiconductor device in FIG. 1.

In FIG. 6, the drift layer 20 made of n-type silicon carbide is formed on the surface of the semiconductor substrate 10 made of n-type silicon carbide having low resistance. As shown in the cross-sectional view of FIG. 6, the second well region 31 made of p-type silicon carbide is provided in the surface layer portion of the drift layer 20 at a position corresponding to the region where the gate wire 82 described in FIG. 1 is provided.

In the active region that is a lower portion of the region where the source electrode 80 described in FIG. 1 is provided, a plurality of the first well regions 30 made of p-type silicon carbide are provided in the surface layer portion of the drift layer 20.

In the surface layer portion of each of the first well regions 30, the source region 40 made of n-type silicon carbide is formed at a position inside from the outer periphery of the first well region 30 by a predetermined distance.

In the surface layer portion of each first well region 30, the contact region 35 made of p-type silicon carbide having low resistance is formed further inside the source region 40, and the first separation region 21 made of silicon carbide is formed further inside the contact region 35 such that the first well region 30 is penetrated. The first separation region 21 is of the same n-type as the drift layer 20, and the n-type impurity concentration of the first separation region 21 may be the same as the n-type impurity concentration of the drift layer 20, or may be higher or lower than the n-type impurity concentration of the drift layer 20.

On the front surface side of the first separation region 21, the Schottky electrode 71 that forms the Schottky connection to the first separation region 21 is formed. Here, the Schottky electrode 71 is preferably formed so as to include at least the corresponding first separation region 21 when viewed from the upper surface.

In addition, the ohmic electrode 70 is formed on the surface of the source region 40, and the source electrode 80 connected to the ohmic electrode 70, the Schottky electrode 71, and the contact region 35 is formed thereon. The first well region 30 can easily exchange electrons and holes with the ohmic electrode 70 via the low-resistance contact region 35.

The region of the drift layer 20 between the adjacent first well regions 30 is the n-type second separation region 22. The n-type impurity concentration of the second separation region 22 may be the same as the n-type impurity concentration of the drift layer 20 or may be higher or lower than the n-type impurity concentration of the drift layer 20. The gate insulating film 50 made of silicon oxide is formed on the surfaces of the adjacent first well regions 30, the second separation region 22 therebetween, and the source region 40 in each of the first well regions 30, and the gate electrode 60 made of polycrystalline silicon is formed on the gate insulating film 50 at least above the first well region 30. The surface layer portion of the first well region 30 facing the gate electrode 60 via the gate insulating film 50 is referred to as the channel region.

The second well region 31 is formed outside the first well region 30 of the outermost periphery of the semiconductor device, and the third separation region 23 is formed between the first well region 30 and the second well region 31. The third separation region 23 is of the same n-type as the drift layer 20, and the n-type impurity concentration of the third separation region 23 may be the same as the n-type impurity concentration of the drift layer 20 or may be higher or lower than the n-type impurity concentration of the drift layer 20. Further, the gate insulating film 50 is formed also on the second well region 31, and a gate electrode 60 electrically connected to the gate electrode 60 formed on the first well region 30 is formed on the gate insulating film 50.

The silicon carbide conductive layer 45 made of silicon carbide, which is of an n-type and has a lower resistance and a higher impurity concentration than the drift layer 20, is formed in a region of a certain proportion of the upper layer portion of the second well region 31. The silicon carbide conductive layer 45 has a sheet resistance lower than that of the second well region 31, and forms a pn junction with the p-type second well region 31. In addition, the silicon carbide conductive layer 45 is formed in the second well region 31 over a width of half or more of the width in the lateral direction of the cross section. The portion where the silicon carbide conductive layer 45 is formed with a width of half or more of the width of the second well region 31 in the lateral direction of the cross section does not need to be the entire cross sections, and may be only a part of the cross sections.

The interlayer insulating film 55 made of silicon oxide is formed between the gate electrode 60 and the source electrode 80. Further, the gate electrode 60 above the second well region 31 and the gate wire 82 are connected to each other via the gate contact hole 95 formed in the interlayer insulating film 55. Further, the p-type silicon carbide junction termination extension (JTE) region 38 is formed on the outer peripheral side of the second well region 31, that is, on the side opposite to the first well region 30. The impurity concentration of the JTE region 38 is lower than the impurity concentration of the second well region 31. The field limiting ring (FLR) may be formed instead of the JTE region 38. Alternatively, a combination of the JTE region 38 and the FLR may be used.

The field insulating film 51 having a larger film thickness than that of the gate insulating film 50, or the gate insulating film 50 is formed on the second well region 31 and the silicon carbide conductive layer 45. An opening, that is, the termination region contact hole 91 is formed in a part of the gate insulating film 50 or the field insulating film 51 on the surface of the silicon carbide conductive layer 45, and the silicon carbide conductive layer 45 is ohmically connected to the source electrode 80 formed thereon via the termination portion ohmic electrode 72 through the opening.

The termination region contact hole 91 penetrates the field insulating film 51 and the interlayer insulating film 55 and allows ohmic connection between the silicon carbide conductive layer 45 and the source electrode 80. The silicon carbide conductive layer 45 and the second well region 31 are not ohmically connected. In addition, the silicon carbide conductive layer 45 has a width larger than the diameter of the termination region contact hole 91. Here, the second well region 31 is not directly ohmically connected to the source electrode 80.

In the active region, the ohmic electrode 70, the Schottky electrode 71, and the contact region 35 are connected to the source electrode 80 via the active region contact hole 90 that is formed by penetrating the interlayer insulating film 55 and the gate insulating film 50. The drain electrode 84 is formed on the rear surface side of the semiconductor substrate 10.

FIG. 7 is a schematic cross-sectional view showing a schematic configuration of the semiconductor device according to Embodiment 1. FIG. 7 shows the surge current conduction region 301, the auxiliary region 302, the active region contact hole 90 formed in the surge current conduction region 301, and the like. The configurations of the surge current conduction region 301 and the auxiliary region 302 in FIG. 7 are the same as those of the stripe-type semiconductor device shown in FIG. 4, and the description thereof will be omitted.

The lattice-type semiconductor device has been described above.

Here, the points common to the stripe-type and lattice-type semiconductor devices will be described. An SBD high surface density structure, for example, a folded structure or the like may be formed in a region of the active region closest to the termination region. In addition, a region in which a large number of SBDs such as a termination portion SBD high surface density structure, for example, JBS, are formed may be formed in a region closest to the active region of the termination region. A sense cell for sensing a current may be provided in the active region. The on-resistance can be reduced by making the concentration of the n-type impurity in the second separation region 22 higher than the concentration of the n-type impurity in the drift layer 20.

Next, a method of manufacturing the SiC-MOSFET with the built-in SBD, which is the semiconductor device of the present embodiment, will be described with reference to the explanatory diagrams of FIG. 8 to FIG. 15.

First, on the semiconductor substrate 10 made of n-type low-resistance silicon carbide having a 4H polytype and a first main surface of (0001) plane orientation with an off angle, the drift layer 20 made of n-type silicon carbide having an impurity concentration from 1×10¹⁵ to 1×10¹⁷ cm⁻³ and a thickness from 5 to 50 μm is epitaxially grown by chemical vapor deposition (CVD).

Subsequently, an implantation mask is formed with a photoresist or the like in a predetermined region of the surface of the drift layer 20, and a p-type impurity, Al (aluminum), is ion-implanted. At this time, the depth of the ion implantation of Al is set to approximately 0.5 to 3 μm, which does not exceed the thickness of the drift layer 20. The impurity concentration of Al that is ion-implanted is in a range from 1×10¹⁷ to 1×10¹⁹ cm⁻³, and is higher than the impurity concentration of the drift layer 20. Thereafter, the implantation mask is removed. The region where Al is ion-implanted in this step is the first well region 30 in the active region and is the second well region 31 in the termination region.

In addition, an implantation mask is formed with a photoresist or the like in a predetermined region of the surface of the drift layer 20 at a position different from the first well region 30 described above, and the p-type impurity, Al (aluminum), is ion-implanted. At this time, the depth of the ion implantation of Al is set to approximately 0.5 to 3 μm so as not to exceed the thickness of the drift layer 20. The impurity concentration of Al that is ion-implanted is in a range from approximately 1×10¹⁷ to 1×10¹⁹ cm⁻³, and is higher than the impurity concentration of the drift layer 20. Thereafter, the implantation mask is removed. The region into which Al is ion-implanted in this step is the auxiliary region 302.

A channel portion is formed on the surface of the auxiliary region 302 in a later step, and the threshold voltage of the channel portion of the auxiliary region 302 should be equal to or higher than the threshold voltage of the channel portion of the active region other than the surge current conduction region 301 and is preferably the same. Therefore, the p-type impurity concentration in the surface of the auxiliary region 302 should be equal to or higher than the p-type impurity concentration in the surface of the first well region 30. In order to achieve this, there is a method of forming the auxiliary region 302 simultaneously with the first well region 30. According to this method, the p-type impurity concentration of the surfaces of the auxiliary region 302 and the first well region 30 can be made the same, and the number of processes can be reduced.

Next, an implantation mask is formed with a photoresist or the like, and the p-type impurity, Al (aluminum), is ion-implanted into the surface of the drift layer 20 in the termination region. At this time, the depth of the ion implantation of Al is set to approximately 0.5 to 3 μm, which does not exceed the thickness of the drift layer 20. The impurity concentration of Al that is ion-implanted is in a range from 1×10¹⁶ to 1×10¹⁸ cm⁻³, which is higher than the impurity concentration of the drift layer 20 and lower than the impurity concentrations of the first well region 30 and the auxiliary region 302. Thereafter, the implantation mask is removed. The region into which Al is ion-implanted in this step is the JTE region 38. Similarly, the contact region 35 is formed by ion implantation of Al into a predetermined region at an impurity concentration in a range from 1×10¹⁶ to 1×10¹⁸ cm⁻³, which is higher than the impurity concentration of the first well region 30 or the auxiliary region 302.

Next, an implantation mask is formed with a photoresist or the like such that predetermined portions thereof inside the first well region 30 and the auxiliary region 302 on the surface of the drift layer 20 are opened, and N (nitrogen) that is an n-type impurity 35 is ion-implanted. The depth of the ion implantation of N is shallower than the thickness of the first well region 30. In addition, the impurity concentration of N that is ion-planted is in a range from 1×10¹⁸ to 1×10²¹ cm⁻³, and exceeds the p-type impurity concentration of the first well region 30 and the auxiliary region 302. A region exhibiting n-type conductivity among the regions into which N is implanted in this step is the source region 40.

Similarly, an implantation mask is formed with a photoresist or the like such that a predetermined portion inside the second well region 31 of the termination region is opened, and N (nitrogen) that is an n-type impurity is ion-implanted. The depth of the ion implantation of N is shallower than the thickness of the first well region 30. The impurity concentration of N that is ion-implanted is in a range from 1×10¹⁸ to 1×10²¹ cm⁻³, and exceeds the p-type impurity concentration of the first well region 30 and the auxiliary region 302. A region exhibiting n-type conductivity among the regions into which N is implanted in this step is the silicon carbide conductive layer 45. The thickness of the silicon carbide conductive layer 45 should be smaller than the thickness of the second well region 31.

The silicon carbide conductive layer 45 and the source region 40 may be formed in the same process with the same thickness and the same impurity concentration, or the silicon carbide conductive layer 45 and the source region 40 may be formed in different processes with different thicknesses and different impurity concentrations.

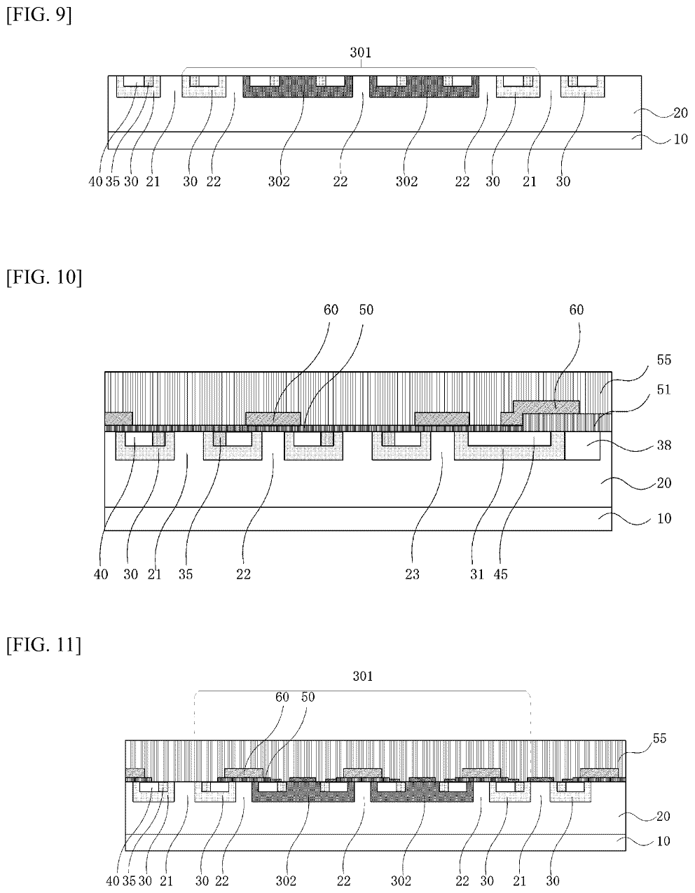

Next, annealing is performed by a heat treatment apparatus in an inert gas atmosphere such as argon (Ar) gas at a temperature from approximately 1300 to 1900 degrees C. for about 30 seconds to 1 hour. By this annealing, N and Al that are ion-implanted are electrically activated. FIG. 8 and FIG. 9 show a cross section that does not include the surge current conduction region 301 and a cross section that includes the surge current conduction region 301, respectively, in the active region at the stage after the ion implantation.

Subsequently, the field insulating film 51 is formed on the semiconductor layer in a region that excludes the active region substantially corresponding to the region where the first well region 30 is formed, and the surge current conduction region 301 by using the CVD method, the photolithography technique, or the like. The field insulating film 51 has a film thickness between approximately 0.5 and 2 μm, which is larger than the film thickness of the gate insulating film 50, and is made of silicon oxide.

Next, the silicon carbide surface not covered with the field insulating film 51 is thermally oxidized to form a silicon oxide film having a desired thickness, that is, the gate insulating film 50. Subsequently, a polycrystalline silicon film being conductive is formed on the gate insulating film 50 and the field insulating film 51 by a low pressure CVD method, and the polycrystalline silicon film is patterned to form the gate electrode 60. Next, an interlayer insulating film 55 made of silicon oxide and having a thickness 35 larger than that of the gate insulating film 50 is formed by the low pressure CVD method. In the active region after the steps up to this stage, a cross section not including the surge current conduction region 301 and a cross section including the surge current conduction region 301 are shown in FIG. 10 and FIG. 11, respectively.

Subsequently, the active region contact hole 90 that penetrates the interlayer insulating film 55 and the gate insulating film 50 and reaches the contact region 35 and the source region 40 in the active region, and the termination region contact hole 91 that penetrates the interlayer insulating film 55 and the gate insulating film 50 and reaches the silicon carbide conductive layer 45 in the termination region are formed. Note that the insulating film at the portions where the Schottky electrode 71 is to be formed inside the active region contact hole 90 and the termination region contact hole 91 are left at this stage.

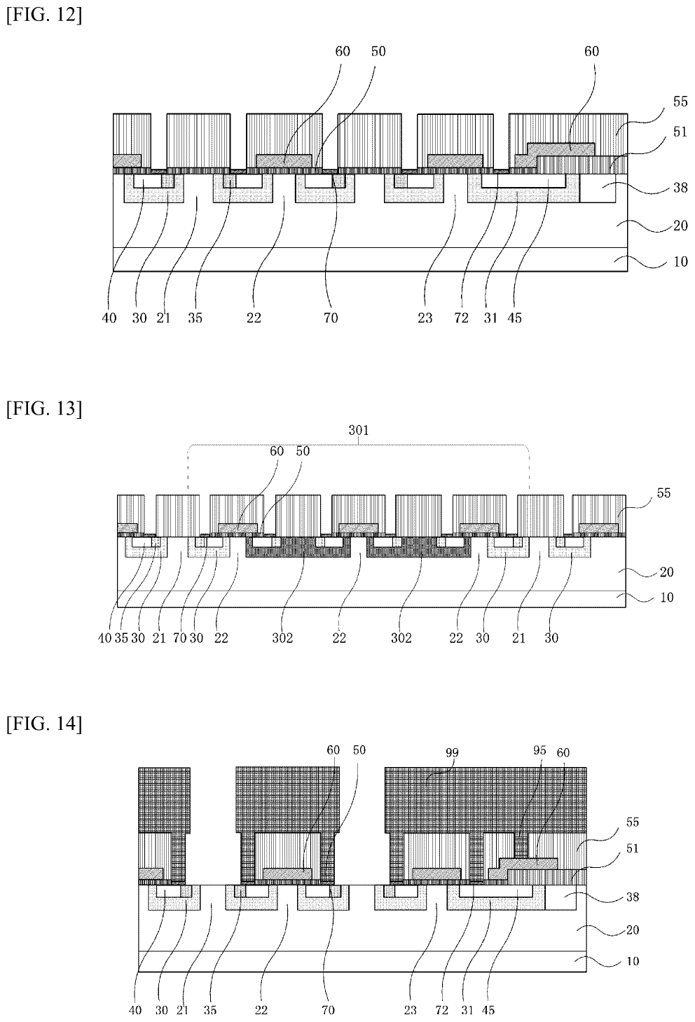

Next, after a metal film containing Ni as a main component is formed by a sputtering method or the like, heat treatment is performed at a temperature from approximately 600 to 1100 degrees C. to cause the metal film containing Ni as a main component to react with the silicon carbide layer inside the active region contact hole 90 and the termination region contact hole 91, thereby forming silicide between the silicon carbide layer and the metal film. Subsequently, the remaining metal film other than the silicide formed by the reaction is removed by wet etching. Thus, the remaining silicide is the ohmic electrode 70 and the termination portion ohmic electrode 72. In the active region after the steps up to this stage, a cross section not including the surge current conduction region 301 and a cross section including the surge current conduction region 301 are shown in FIG. 12 and FIG. 13, respectively.

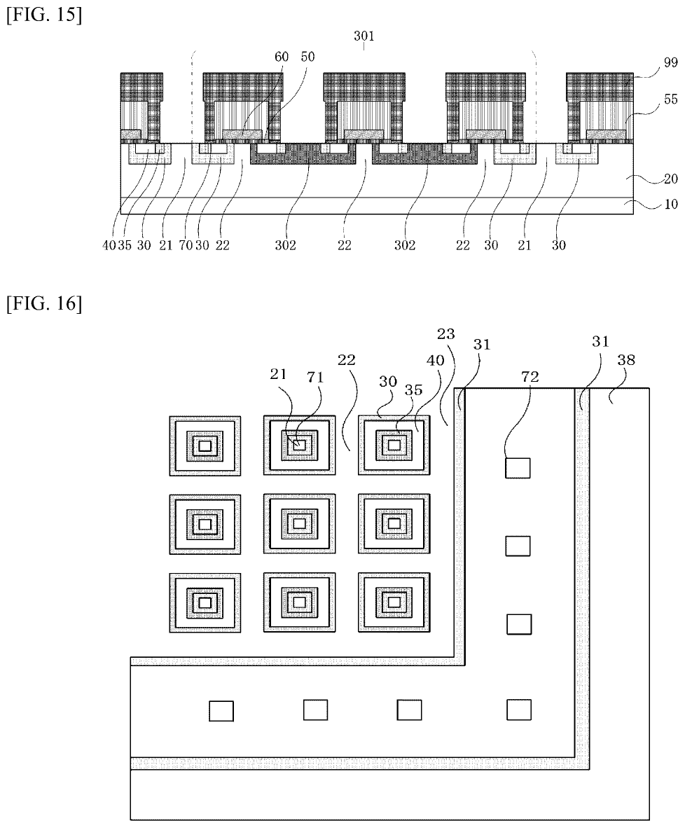

Subsequently, a metal film containing Ni as a main component is formed on the rear surface (second main surface) of the semiconductor substrate 10, and is subjected to heat treatment, thereby forming a rear surface ohmic electrode (not shown) on the rear side of the semiconductor substrate 10. Next, a resist mask 99 is formed, and the interlayer insulating film 55 and the gate insulating film 50 on the first separation region 21 and the auxiliary region 302 are removed, and the interlayer insulating film 55 at a position for the gate contact hole 95 to be formed is also removed. The removal method is wet etching that does not damage the surface of the silicon carbide layer to be served as the Schottky interface, but dry etching may also be used. In the active region after the steps up to this stage, a cross section not including the surge current conduction region 301 and a cross section including the surge current conduction region 301 are shown in FIG. 14 and FIG. 15, respectively.

Subsequently, after the resist mask 99 is removed, a metal film to be the Schottky electrode 71 is deposited by sputtering or the like, and the Schottky electrode 71 is formed on the first separation region 21 in the active region contact hole 90 using patterning with a photoresist or the like. The material of the Schottky electrode 71 should be Ti, Mo, or: the like. Further, the Schottky electrode 71 may formed separately in the individual active region contact hole 90 by the patterning or may be formed to be one surface on which the source electrode 80 is to be formed. Then, the patterning for the Schottky electrode 71 and the source electrode 80 can be performed at a time, and the number of processes can be reduced.

Next, a wiring metal such as Al is formed on the surface of the substrate processed so far by sputtering or vapor deposition, and is processed into a predetermined shape by photolithography, thereby forming the source electrode 80 in contact with the ohmic electrode 70, the termination portion ohmic electrode 72, and the Schottky electrode 71 on the source side, and the gate pad 81 and the gate wire 82 in contact with the gate electrode 60. Further, the drain electrode 84, which is a metal film, is formed on the surface of the rear surface ohmic electrode (not shown).

In this way, the semiconductor device of the present embodiment shown in FIG. 1 to FIG. 7 can be manufactured.

Next, the operation of the SiC-MOSFET with the built-in SBD, which is the semiconductor device of the present embodiment, will be described. Here, a semiconductor device made of 4H type silicon carbide is taken as an example, and four states in the normal operation and one abnormal state are separately described. When the semiconducting material is 4H type silicon carbide, the diffusion potential of the pn junction is approximately 2V.

The first state in the normal operation is a state in which a high voltage relative to the source electrode 80 is applied to the drain electrode 84 and a positive voltage equal to or higher than a threshold voltage is applied to the gate electrode 60, and is hereinafter referred to as an “on-state”.

In the on-state, an inversion channel is formed in the channel region, and a path through which electrons serving as carriers flow is formed between the n-type source region 40 and the n-type second separation region 22. On the other hand, since an electric field (reverse bias) in a direction in which a current is hard to flow for the Schottky connection, that is, in a reverse direction, is applied to the Schottky junction formed in the contact portion between the first separation region 21 and the Schottky electrode 71, a current does not flow.

Electrons flowing from the source electrode 80 to the drain electrode 84 follow an electric field formed by a positive voltage applied to the drain electrode 84, and reach the drain electrode 84 from the source electrode 80 via the ohmic electrode 70, the source region 40, the channel region, the second separation region 22, the drift layer 20, and the semiconductor substrate 10. Therefore, by applying a positive voltage to the gate electrode 60, an on-current flows from the drain electrode 84 to the source electrode 80.

The voltage applied between the source electrode 80 and the drain electrode 84 at this time is referred to as an on-voltage. A value obtained by dividing the on-voltage by the density of the on-current is referred to as an on-resistance, and the on-resistance is equal to the sum of resistances of paths through which electrons flow from the source electrode 80 to the drain electrode 84. Since the product of the on-resistance and the square of the on-current is equal to the conduction loss consumed by the MOSFET during conduction, the on-resistance should be preferably low.

In the present embodiment, since a channel structure is formed in the surge current conduction region 301, the surge current conduction region 301 can be a path for electrons flowing from the source electrode 80 to the drain electrode 84 in the on-state. Therefore, the surge current conduction region 301 can contribute to the reduction in the on-resistance.

The second state in the normal operation is a state in which a high voltage relative to the source electrode 80 is applied to the drain electrode 84 and a voltage equal to or lower than the threshold voltage is applied to the gate electrode 60, and is hereinafter referred to as an “off-state”.

In the off-state, since no inversion carrier exists in the channel region, the on-current does not flow, and in the on-state, a high voltage applied to a load such as an inverter is applied between the source electrode 80 and the drain electrode 84 of the MOSFET.

Although no current ideally flows through the Schottky junction formed at the contact portion between the first separation region 21 and the Schottky electrode 71 because an electric field in the same direction as that in the on-state is applied to the Schottky junction, a leakage current may be generated because an electric field much higher than that in the on-state is applied to the Schottky junction. If the leakage current is large, heat generation of the MOSFET increases, and the MOSFET and a module using the MOSFET may be thermally destroyed. Therefore, it is preferable to suppress the electric field applied to the Schottky junction to be low in order to reduce the leakage current.

The third state in the normal operation is a state in which a low voltage relative to the source electrode 80 is applied to the drain electrode 84, that is, a reverse electromotive voltage, is applied to the MOSFET, and a voltage less than the threshold value is applied to the gate electrode 60, and a freewheeling current flows from the source electrode 80 toward the drain electrode 84. Hereinafter, this state is referred to as an “asynchronous rectification state”

In the asynchronous rectification state, in the active region other than the surge 30) current conduction region 301, a forward electric field (forward bias) is applied to the Schottky junction formed at the contact portion between the first separation region 21 and the Schottky electrode 71, and a unipolar current composed of an electron current flows from the Schottky electrode 71 toward the n-type first separation region 21. Here, the freewheeling current component of a freewheeling diode is mainly the unipolar component. In addition, the source electrode 80 and the first well region 30 are at the same potential via the ohmic electrode 70.

As a result, a forward bias is also applied to the pn junction between the p-type first well region 30 and the n-type drift layer 20. Here, the pn junction is formed in parallel with the above-described Schottky junction, and the threshold voltage of the Schottky junction is lower than the threshold voltage of the pn junction. Therefore, when the state changes from the off-state to the asynchronous rectification state, the freewheeling current mainly flows through the Schottky junction, and can be suppressed from flowing through the pn junction.

In addition, only the unipolar current can flow through the Schottky junction, even when the voltage applied between the source electrode 80 and the drain electrode 84 exceeds the diffusion potential of the pn junction. This is because a unipolar current flows in the drift layer 20 due to the voltage applied between the source electrode 80 and the drain electrode 84, a voltage drop occurs in the drift layer 20, and the voltage applied to the pn junction is a voltage obtained by subtracting the voltage drop from the voltage applied between the source electrode 80 and the drain electrode 84, so that the unipolar current does not flow through the pn junction. Therefore, a voltage exceeding the diffusion potential of the pn junction can be applied between the source electrode 80 and the drain electrode 84.

In this way, when the SBD is incorporated in a semiconductor device having a MOSFET or the like, it is possible to suppress a forward current, which is the bipolar current, from flowing through the pn junction even in the asynchronous rectification state. When the bipolar current flows through the pn junction and a starting point such as a basal plane dislocation exists in such a portion, stacking fault expands. Since the stacking fault blocks a current flowing in the thickness direction of the semiconductor device, the 20 on-resistance increases when the stacking fault expands, which may lead to device failure due to the thermal runaway. The SBD is built in the semiconductor device, whereby the bipolar current can be suppressed from flowing through the pn junction at the time of the freewheeling, and the reliability of the semiconductor device can be enhanced.

On the other hand, in the asynchronous rectification state, the unipolar current is less likely to flow in the surge current conduction region 301 because the first separation region 21 connected to the Schottky electrode 71 is not present. The unipolar current flowing in the drift layer 20 via the junction between the Schottky electrode 71 and the first separation region 21 that are adjacent to the surge current conduction region 301 diffuses in the planar direction in the drift layer 20 and some of them flows in the drift layer 20 in the surge current conduction region 301. The current density of the unipolar current is smaller than the current density of the unipolar current flowing in the region other than the surge current conduction region 301.

Therefore, the bipolar current flowing through the pn junction in the surge current conduction region 301 is larger than the bipolar current flowing through the pn junction in the active region other than the surge current conduction region 301. Therefore, it is considered that the stacking fault expands in the surge current conduction region 301 and the on-resistance of the semiconductor device increases, but for example, if the area of the surge current conduction region 301 is 10% or less of the entire semiconductor device, even if the stacking fault expands in the entire surge current conduction region 301, the increase in the on-resistance of the semiconductor device can be suppressed to about 10% or less. Typically, in consideration of manufacturing variations in the on-resistance and the thermal resistance, a design margin of about 20% is provided for the on-resistance, and therefore, by setting the surge current conduction region 301 to 20% or less, more preferably 10% or less, of the active region, thermal runaway breakdown due to the increase in the on-resistance can be avoided.

In the fourth state of the normal operation, a freewheeling current flows from the source electrode 80 to the drain electrode 84 in a state where a lower voltage at the drain electrode 84 relative to the source electrode 80, that is, a reverse electromotive voltage, is applied to the MOSFET and a voltage equal to or higher than the threshold voltage is applied to the gate electrode 60. Hereinafter, this state is referred to as a “synchronous rectification state”.

In the synchronous rectification state, a unipolar current flows through the Schottky electrode 71 and a unipolar current flows through the channel. In the present embodiment, since the channel is formed also in the surface of the auxiliary region 302, that is, in the surge current conduction region 301, the channel current flows also in the surge current conduction region 301, and the channel current serves as the unipolar current. Therefore, even when the surge current conduction region 301 does not have a junction between the Schottky electrode 71 and the first separation region 21, the pn junction can be prevented from being turned on in the surge current conduction region 301.

The fact that the channel current flows also in the surge current conduction region 301 brings about a remarkable effect in that the concentration of heat generation during the synchronous rectification state is suppressed. First, in the case of an inverter operation, for example, the operation time in the synchronous rectification state occupies about half of the carrier period, and is assumed to be a long time of about several tens of us to several ms. This is much longer than the time of the asynchronous rectification state, which is assumed to be as short as several hundred ns to several us. If the current continues to flow through the pn junction for such a long time, local heat generation occurs. This is because the bipolar current has an effect of generating conductivity modulation and reducing the resistance of the drift layer, relative to the unipolar current.

In the region where the bipolar current flows, the resistance decreases, and a larger amount of current flows than in the region where only the unipolar current flows. As a result, the local temperature of the region where the bipolar current flows rise, the conductivity modulation becomes stronger, and positive feedback in which current concentration occurs starts. As a result, there is a possibility that reliability deterioration such as cracking of the electrode junction portion and destruction of the gate insulating film 50 may occur. In the structure shown in the present embodiment, the operation of the pn junction in the surge current conduction region 301 can be suppressed even during the synchronous rectification state, and high reliability can be obtained by avoiding the local heat generation.

The abnormal state is a state in which a surge current flows between the source electrode 80 and the drain electrode 84, and this will be described. This indicates a state in which a current exceeding a rated current flows from the source electrode 80 to the drain electrode 84 instantaneously when an inverter accident occurs or when the power supply of the converter is turned on. In many cases, it is assumed that the off-signal is applied to the gate electrode 60, and no current flows in the channel region. In such a case, the semiconductor device is required not to fail due to heat generation, and the allowable current at this time is called surge tolerance. In order to increase the surge tolerance, it is important to provide a low-resistance region to allow the surge current to flow therethrough, thereby reducing the heat generation of the semiconductor device.

However, such an abnormal state is not recognized as a problem or is hardly recognized as a problem because the frequency of the abnormal state is low.

From the viewpoint of increasing the surge tolerance, it is preferable to use the bipolar current that greatly affects the conductivity modulation. When the surge current starts to flow in the semiconductor device, the unipolar current is less likely to flow because the surge current conduction region 301 does not include the first separation region 21 connected to the Schottky electrode 71. Therefore, compared with the active region other than the surge current conduction region 301, the pn junction is more likely to be turned on and the conduction of the bipolar current is more likely to start.

In this state, when the surge current increases with time and reaches a large current exceeding the rated current, the bipolar current flowing from the surge current conduction region 301 increases, and holes diffuse from the surge current conduction region 301 toward the active region outside the surge current conduction region 301. In the active region outside the surge current conduction region 301 that has affected by the diffusion of the holes, the resistance of the drift layer 20 decreases, the unipolar current density increases, and the pn junction is turned on. Then, the holes are diffused toward a further outer region, and the pn diode is turned on in the region. That is, when the surge current conduction occurs, the surge current conduction region 301 becomes the starting point and a chain of pn diodes turns on in the surrounding area one after another toward the outside of the surge current conduction region 301.

As a result, the pn diode is turned on over a wide range of the semiconductor device, and a bipolar conduction state is achieved, so that the heat generation of the semiconductor device can be suppressed. That is, the allowable surge current can be increased, and the surge tolerance can be increased.

As described above, the surge current conduction region 301 can not only increase the current that can flow in the surge current conduction region 301, but also change the characteristics of the semiconductor device over a wide range by the chain reaction. Therefore, it is not necessary to excessively increase the area occupied by the one or more surge current conduction regions 301 in the semiconductor device. On the other hand, the surge current conduction region 301 may cause bipolar operation during the asynchronous rectification state, and may cause deterioration in reliability due to expansion of the stacking fault. Therefore, the area of the surge current conduction region 301 or the sum of the areas of the surge current conduction regions 301 in a plan view is preferably 20% or less, more preferably 10% or less of the area of the entire semiconductor device. In this way, it is possible to suppress characteristic deterioration due to expansion of the stacking fault and the thermal runaway due to the fault, and to improve the surge tolerance.

When a plurality of the surge current conduction regions 301 are formed, the separation distance between any two of the surge current conduction regions 301 may be three times or more the width of the surge current conduction region 301, and preferably ten times or more. Here, the width of the surge current conduction region 301 corresponds to a separation distance between the two first separation regions 21 provided each adjacent on one end side and the other end side of the surge current conduction region 301. When the separation distance is set to be three times or more the width of the surge current conduction region 301, even in the case where the surge current conduction region 301 is formed in a square shape, the ratio of the surge current conduction region 301 to the entire semiconductor device can be 10% or less. Further, when the separation distance is set to be 10 times or more the width of the surge current conduction region 301, even in the case where the surge current conduction region 301 is formed in a rectangular shape, traversing from one end to the other end of the active region, the ratio of the surge current conduction region 301 to the entire semiconductor device can be 10% or less.

In order for the surge current conduction region 301 to effectively serve as a starting point of the pn diode operation when the surge current starts to flow in the semiconductor device, it is important to reduce the density of the unipolar current that diffuses from the outside of the surge current conduction region 301 to the surge current conduction region 301. The unipolar current density strongly depends on the distance from the surge current conduction region 301 to the connection portion between the Schottky electrode 71 and the first separation region 21, and decreases as the distance increases. Therefore, it is preferable to form the surge current conduction region 301 to be wide, and it is necessary to make the distance between the first separation regions 21 larger than the separation distance between the adjacent first separation regions 21 at least in the active region outside the surge current conduction region 301. That is, the surge current conduction region 301 is formed over a region larger than the first width of the first well region 30 in a plan view.

In the present embodiment, the active region second contact hole 90B is formed in the surge current conduction region 301 to connect the source electrode 80 and the auxiliary region 302. With this configuration, when a surge current flows through the semiconductor device, the surge current can pass through a short path having a relatively small resistance in the vertical direction of the cross section, that is, a large surge current can flow.

In order to further increase the surge tolerance, it is preferable to form a plurality of the surge current conduction regions 301 and arrange them evenly over the entire active region. That is, as described for the stripe-type structure of the present embodiment, the surge current conduction regions 301 are preferably provided periodically or at equal intervals in at least one direction of the semiconductor device in a plan view. In this way, when a surge current flows in the semiconductor device and the on-operation of the pn diode is chained to the periphery with the surge current conduction region 301 as a starting point, the on-operation of the pn diode can be chained evenly in the entire semiconductor device. Thus, the heat generation points in the semiconductor device can be dispersed.

Further, when the semiconductor device is the lattice type, the corner portion of the chip in the termination region is like a schematic plan view of the schematic configuration of the semiconductor device according to Embodiment 1, for example, as shown in in FIG. 16. In FIG. 16, a surge current conduction region 301 may be provided.

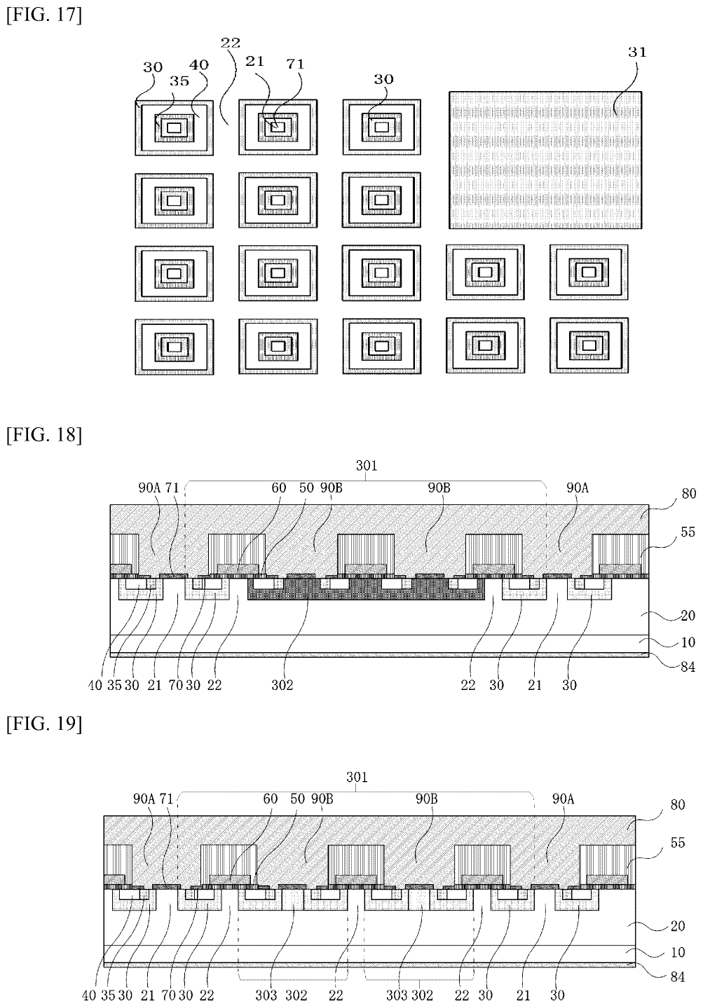

In addition, when the semiconductor device is the lattice type, the corner portion of the gate pad 81 is like a schematic plan view of the schematic configuration of the semiconductor device according to Embodiment 1, for example, as shown in FIG. 17. In FIG. 17, the gate pad 81 is formed at a position where the large second well region 31 is formed. In FIG. 17, a surge current conduction region 301 may be provided.

### Embodiment 2

FIG. 18 is a schematic cross-sectional view showing a schematic configuration of a semiconductor device according to Embodiment 2. The present embodiment is different from Embodiment 1 in that the second separation region 22 of the first conductivity type adjacent to the auxiliary region 302 or the first well region 30, connected to the drift layer 20, and opposed to the gate electrode 60 via the gate insulating film 50 is not provided, that is, the second separation region 22 is not formed in the surge current conduction region 301, and the auxiliary regions 302 are continuously formed. The other configurations are the same.

In the surge current conduction region 301 of the present embodiment, a region combining the first well regions 30, the first separation regions 21, and the second separation regions 22 is replaced with an auxiliary region 302.

In this way, since no channel is formed in the surge current conduction region 301, the pn diode formed of the auxiliary region 302 and the drift layer 20 in the surge current conduction region 301 is turned on not only when the gate is turned off but also when the gate is turned on in the semiconductor device, and with a starting point of the above, the on-operation of the pn diode is easily propagated to the outside of the surge current conduction region 301, thereby improving the surge tolerance.

### Embodiment 3

FIG. 19 is a schematic cross-sectional view showing a schematic configuration of a semiconductor device according to Embodiment 3. The present embodiment is different from Embodiment 1 in that the first separation region 21 of the surge current conduction region 301 is replaced with the p-type hole filling auxiliary region 303, and the other configurations are the same.

In the surge current conduction region 301 of the present embodiment, a region combining the first well regions 30 and the hole filling auxiliary region 303 is replaced with the auxiliary region 302.

Even in this case, the junction between the Schottky electrode 71 and the first separation region 21 can be eliminated in the surge current conduction region 301, and a pn diode can be formed. These effects are the same as those described in Embodiment 1 and Embodiment 2.

The hole filling auxiliary region 303 may be formed in the p-type ion implantation step, and an increase in the number of steps can be avoided if the hole filling auxiliary region is formed simultaneously with the JTE region 38 or the contact region 35.

Embodiment 4

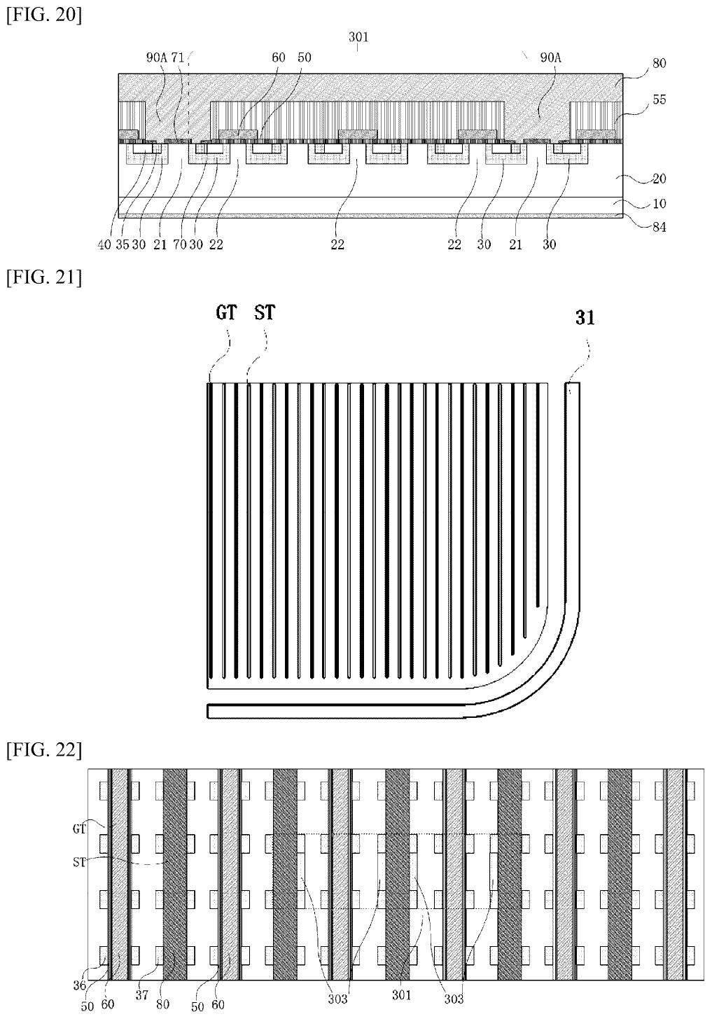

FIG. 20 is a schematic cross-sectional view showing a schematic configuration of a semiconductor device according to Embodiment 4. In the present embodiment, compared with Embodiment 2, the auxiliary region 302 is not formed in the surge current conduction region 301, and the first well region 30, the source region 40, the gate electrode 60, and the like are arranged in the same manner as in the active region around the surge current conduction region 301.

The auxiliary region 302 and the active region second contact hole 90B are not formed, and thus the connection with the Schottky electrode 71 and the first separation region 21 are shut out. Since the active region second contact hole 90B is not present in the surge current conduction region 301, the effect achieved in the present embodiment is the same as that in Embodiment 2.

Note that, although the active region has been described so far as having a unit cell structure in which the SBD and the MOSFET are integrated, the SBD and the MOSFET may be arranged in parallel in the unit cell formed in the active region.

### Embodiment 5

FIG. 21 is a schematic plan view showing a schematic configuration of a semiconductor device according to Embodiment 5. FIG. 21 mainly shows a part of the silicon carbide semiconductor in FIG. 1. In the semiconductor device shown in FIG. 21, in the active region, gate trenches GT in a stripe shape in which transistors are formed and Schottky trenches ST in a stripe shape in which the Schottky electrodes 71 are embedded are alternately arranged in parallel with each other. In addition, the second well region 31 is formed in the termination region around the active region.

FIG. 22 is a schematic plan view showing a schematic configuration of the semiconductor device according to Embodiment 5, and is an enlarged view of the active region of the semiconductor device. First connection regions 36 and second connection regions 37 made of p-type silicon carbide are formed at constant intervals on the side of the gate trenches GT and the side of the Schottky trenches ST, respectively. In the surge current conduction region 301, the hole filling auxiliary region 303 is formed between the adjacent second connection regions 37 on the side of the Schottky trench ST.

The termination region of the semiconductor device may be formed in the same manner as the planar type MOSFET with the built-in SBD, or may have another structure in accordance with a trench type. Here, only the active region will be described.

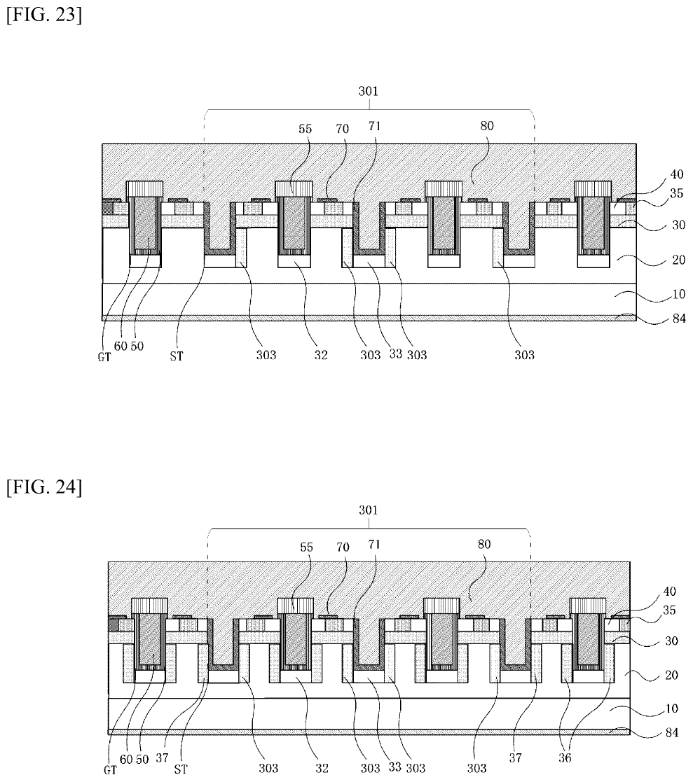

FIG. 23 is a schematic cross-sectional view showing a schematic configuration of the semiconductor device according to Embodiment 5. FIG. 23 shows a cross section of a portion in which the hole filling auxiliary regions 303 are formed in the surge current conduction region 301 and the first connection region 36 and the second connection region 37 are not formed in FIG. 22.

FIG. 24 is a schematic cross-sectional view showing a schematic configuration of the semiconductor device according to Embodiment 5. FIG. 24 shows a cross section of a portion in which the hole filling auxiliary region 303 is formed in the surge current conduction region 301 and the first connection region 36 and the second connection region 37 are formed in FIG. 22.

In FIG. 23 and FIG. 24, the drift layer 20 made of n-type silicon carbide is formed on the surface of the semiconductor substrate 10 made of n-type silicon carbide having low resistance. The first well region 30 made of p-type silicon carbide is formed in the surface layer portion of the drift layer 20.

The source region 40 made of n-type silicon carbide is formed in a part of the surface layer portion on the first well region 30. The low-resistance p-type contact region 35 is formed adjacent to the source region 40 in a part of the surface layer portion on the first well region 30.

In the active region, the gate trench GT is formed to penetrate the source region 40 and the first well region 30 and reaches the drift layer 20. Further, the Schottky trench ST is formed at another location to penetrate the source region 40 and the first well region 30 and reaches the drift layer 20.

The gate trenches GT and the Schottky trenches ST are alternately arranged in parallel with each other. The gate trenches GT and the Schottky trenches ST may be formed to have the same depth or different depths to each other. The gate trenches GT and the Schottky trenches ST may be formed to have the same width or different widths to each other.

The gate electrode 60 is formed in the gate trench GT via the gate insulating film 50 made of silicon oxide. The gate electrode 60 is made of polycrystalline silicon having a high impurity concentration and a low resistance. The interlayer insulating film 55 made of silicon oxide is formed on the gate electrode 60. The Schottky electrode 71 and the source electrode 80 are formed in the Schottky trench ST, and the Schottky electrode 71 is formed in contact with the drift layer 20 and forms the Schottky connection to the drift layer 20.

A p-type first protection region 32 is formed below the gate trench GT in the drift layer 20. A p-type second protection region 33 is formed below the Schottky trench ST in the drift layer 20. The first protection region 32 and the second protection region 33 have the same depth and the same impurity concentration. The first protection region 32 and the first well region 30 are connected via the p-type first connection region 36. The second protection region 33 and the first well region 30 are connected via the p-type second connection region 37.

The ohmic electrode 70 is formed on the surface of the source region 40, and the source electrode 80 connected to the ohmic electrode 70, the Schottky electrode 71, and the contact region 35 is formed thereon. The first well region 30 can easily exchange electrons and holes with the ohmic electrode 70 via the low-resistance contact region 35. The source electrode 80 is also connected to the Schottky electrode 71 in the Schottky trench ST.

A region which is a region along the side surface of the gate trench GT of the first well region 30 and faces the gate electrode 60 via the gate insulating film 50 is referred to as a channel region. Further, the Schottky diode is formed in a region where the Schottky electrode 71 and the drift layer 20 are in contact with each other on the side surface of the Schottky trench ST. The drain electrode 84 is formed on the rear surface side of the semiconductor substrate 10.

In the present embodiment, the first separation region 21 corresponds to a region that is in contact with the side surface of the Schottky trench ST and is between the first well region 30 and the second protection region 33 that are in contact with the Schottky trench ST. Further, the second separation region 22 corresponds to a region that is in contact with the side surface of the gate trench GT and is between the first well region 30 and the first protection region 32 that are in contact with the gate trench GT.

In the surge current conduction region 301 shown in FIG. 23 and FIG. 24, the first separation region 21 is replaced with the hole filling auxiliary region 303 that is in contact with the side surface of the Schottky trench ST. Further, the Schottky electrode 71 is not connected to the n-type first separation region 21 by the p-type hole filling auxiliary region 303.

The second well region 31 of the termination region may be formed at the same depth as the first well region 30 of the active region, or may be formed at the same depth as the first protection region 32 and the second protection region 33 in the active region, that is, at the depth of the bottom of the gate trench GT and the Schottky trench ST. Further, the low-resistance n-type silicon carbide conductive layer 45 may be formed in the surface layer portion of the second well region 31. Further, the second well region 31 may not be directly ohmically connected to the source electrode 80.

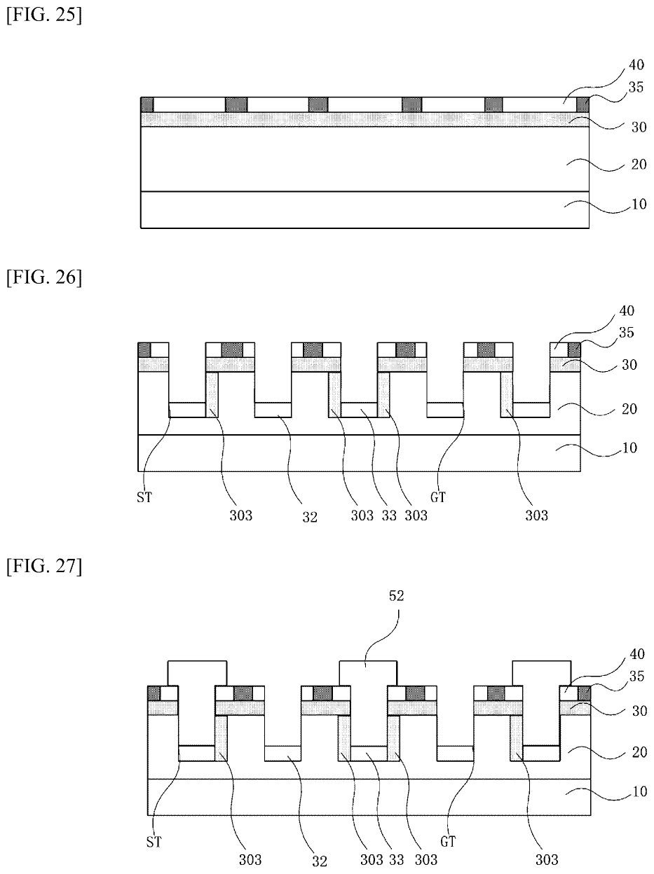

Next, a method of manufacturing the SiC-MOSFET with the built-in SBD in the trench type, which is the semiconductor device of the present embodiment, will be described with reference to the explanatory diagrams of FIG. 25 to FIG. 30. Here, a cross section of a portion where the surge current conduction region 301 is formed and the first connection region 36 and the second connection region 37 are not formed is shown.

First, the semiconductor substrate 10, which is made of n-type low-resistance silicon carbide having a 4H polytype and a first main surface of (0001) plane orientation with an off angle, is prepared. Then, the drift layer 20 made of n-type silicon carbide is epitaxially grown on the semiconductor substrate 10 by a CVD method. The drift layer 20 has an impurity concentration from approximately 1×10¹⁵ to 1×10¹⁷ cm⁻³ and the thickness thereof is from approximately 5 to 50 μm.

Subsequently, p-type impurities of Al are ion-implanted into the surface of the drift layer 20. At this time, the depth of the ion implantation of Al is set to approximately 0.5 to 3 μm, which does not exceed the thickness of the drift layer 20. The impurity concentration of Al that is ion-implanted is in a range from approximately 1×10¹⁷ to 1×10¹⁹ cm⁻³, and is higher than the impurity concentration of the drift layer 20. The region where Al is ion-implanted in this step serves as the first well region 30. In the termination region, this region serves as the second well region 31. The first well region 30 may be formed on the drift layer 20 by an epitaxial method.

Next, the contact region 35 is formed by ion-implanting Al into a predetermined region of a surface layer portion of the first well region 30 at an impurity concentration in a range from approximately 1×10¹⁶ to 1×10¹⁸ cm⁻³ so as to be higher than the impurity concentration of the first well region 30. Further, n-type impurities of N are ion-implanted into a predetermined region of a surface layer portion of the first well region 30 on the surface of the drift layer 20. The depth of the ion implantation of N is shallower than the thickness of the first well region 30. The impurity concentration of N that is ion-implanted is in a range from approximately 1×10¹⁸ to 1×10²¹ cm⁻³, and exceeds the p-type impurity concentration of the first well region 30. A region exhibiting n-type conductivity in the region into which N is implanted in this step serves as the source region 40. FIG. 25 is a cross-sectional view of the active region at this stage.

Next, the gate trench GT is formed at a position where the source region 40 is formed, and the Schottky trench ST is formed at a position where the source region 40 and the contact region 35 are not formed. P-type impurities of Al are implanted into the bottom portions of the gate trench GT and the Schottky trench ST, thereby forming the first protection region 32 at the bottom of the gate trench GT and the second protection region 33 at the bottom of the Schottky trench ST. The impurity concentration of the first protection region 32 and the second protection region 33 should be in a range from approximately 1×10¹⁷ to 1×10¹⁹ cm⁻³.

The first connection region 36 and the second connection region 37 formed so as to be respectively in contact with the gate trench GT and the Schottky trench ST may be formed by oblique ion implantation in which ions of a p-type impurity such as Al are obliquely implanted from a direction orthogonal to the extending direction of each trench in a plan view. The impurity concentration of the first connection region 36 and the second connection region 37 should be in a range from approximately 1×10¹⁷ to 1×10¹⁹ cm⁻³.

The hole filling auxiliary region 303, which is a feature of the present disclosure, may also be formed by oblique ion implantation in which ions of a p-type impurity such as Al are implanted obliquely from a direction orthogonal to the extending direction of each trench in a plan view, similarly to the first connection region 36 and the second connection region 37. The impurity concentration of the first connection region 36 and the second connection region 37 should be in a range from approximately 1×10¹⁷ to 1×10¹⁹ cm⁻³. The hole filling auxiliary region 303 can be formed simultaneously with the first connection region 36 or the second connection region 37, and can also be formed simultaneously with the first connection region 36 and the second connection region 37 when the first connection region 36 and the second connection region 37 are formed simultaneously. By forming the structure in this manner, the number of steps can be reduced, and the structure can be easily manufactured.

Here, when the plane orientation of the first main surface of the semiconductor substrate 10 is a (0001) plane having an off angle in the <11-20> direction, both the gate trench GT and the Schottky trench ST in the active region should be formed in parallel to the <11-20> direction. In this way, the plane orientation of the trench side walls on both sides of the gate trench GT is not affected by the off direction of the substrate, and thus the threshold voltage of the MOSFET of the gate trench GT is not affected by the off direction of the substrate, and thus the variation in the threshold voltage of the MOSFET can be reduced. Further, since the plane orientation of the trench side walls on both sides of the Schottky trench ST is also not affected by the off direction of the substrate, the variation in the barrier height of the Schottky interface of the Schottky trench ST can be reduced.

Next, annealing is performed by a heat treatment apparatus in an inert gas atmosphere such as argon (Ar) gas at a temperature from approximately 1300 to 1900 degrees C. for about 30 seconds to 1 hour. By this annealing, N and Al that are ion-implanted are electrically activated. FIG. 26 is a cross-sectional view of the active region at this stage.

Subsequently, as shown in FIG. 27, the inside of the Schottky trench ST is filled with a protective insulating film 52 such as silicon oxide.

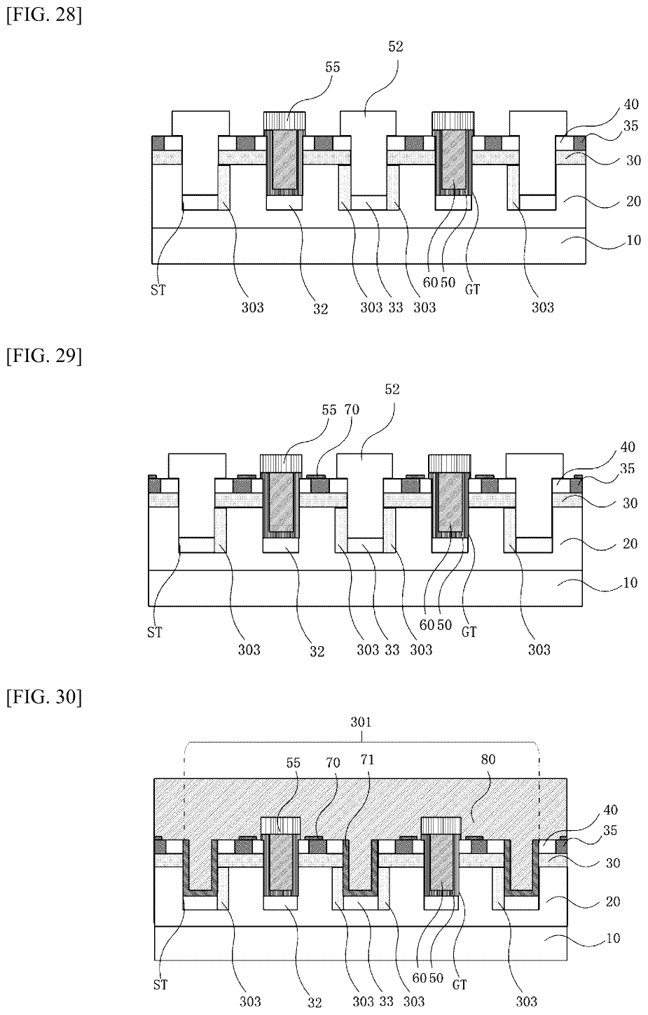

Next, the silicon carbide surface not covered with the protective insulating film 52 is thermally oxidized to form a silicon oxide film as the gate insulating film 50 having a desired thickness. Subsequently, a polycrystalline silicon film having conductivity is formed on the gate insulating film 50 by the low pressure CVD method, and the polycrystalline silicon film is patterned to form the gate electrode 60. Next, the interlayer insulating film 55 made of silicon oxide and having a thickness larger than that of the gate insulating film 50 is formed by the low pressure CVD method. Subsequently, the interlayer insulating film 55 and the gate insulating film 50 are removed by wet etching such that the contact region 35 and the source region 40 in the active region are exposed. FIG. 28 is a cross-sectional view of the active region at this stage.

Subsequently, a metal film containing Ni as a main component is formed by sputtering or the like on the surface where the interlayer insulating film 55 and the gate insulating film 50 are removed and thus the source region 40 and the contact region 35 are exposed, and then heat treatment at a temperature from approximately 600 to 1100 degrees C. is performed to react the metal film containing Ni as the main component with the silicon carbide layer to form silicide between the silicon carbide layer and the metal film. Subsequently, the remaining metal film other than the silicide formed by the reaction is removed by wet etching. Thus, the remaining silicide is the ohmic electrode 70. FIG. 29 is a cross-sectional view of the active region after the steps up to this stage.

Next, the protective insulating film 52 in the Schottky trench ST is removed by hydrofluoric acid or the like, and the Schottky electrode 71 is formed in the Schottky trench ST. The material of the Schottky electrode 71 should be Ti, Mo, or the like. Subsequently, the source electrode 80 mainly made of Al is formed so as to be connected to the Schottky electrode 71 and the ohmic electrode 70. The gate pad 81 and the gate wire 82 may be formed simultaneously with the source electrode 80. FIG. 30 is a cross-sectional view of the active region after the steps up to the stage where the source electrode 80 is formed.

Further, the drain electrode 84, which is a metal film, is formed on the surface of a rear surface ohmic electrode (not shown) formed on the rear surface of the substrate. In this way, the semiconductor device of the present embodiment, the cross-sectional views of which are shown in FIG. 23 and FIG. 24, can be manufactured.

The operation and the effect of the surge current conduction region 301 in the operation in the SiC-MOSFET with built-in SBD in the trench type as the semiconductor device of the present embodiment are the same as the operation and the effect of the surge current conduction region 301 in the operation in the planar type SiC-MOSFET with built-in SBD, and thus the description thereof will be omitted.

### Embodiment 6

In the present embodiment, the semiconductor device according to Embodiment 1 to Embodiment 5 described above is applied to a power conversion device, and a power conversion system is configured to include the power conversion device. Although the present disclosure is not limited to a specific power conversion device, an example of a three-phase inverter will be described below.

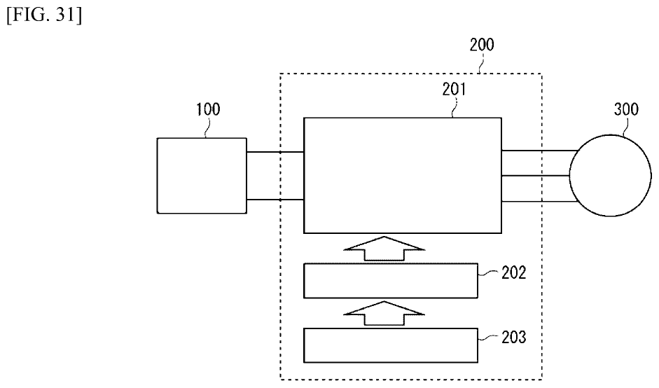

FIG. 31 is a schematic diagram showing a schematic configuration of the power conversion system to which the power conversion device 200 according to Embodiment 6 is applied.

The power conversion system shown in FIG. 31 includes a power supply 100, a power conversion device 200, and a load 300. The power supply 100 is a DC power supply and supplies DC power to the power conversion device 200. The power supply 100 can be configured with various types, and for example, can be configured with a DC system, a solar cell, or a storage battery, or may be configured with a rectifier circuit or an AC/DC converter connected to an AC system. Further, the power supply 100 may be configured with a DC/DC converter that converts DC power output from a DC system into predetermined power.

The power conversion device 200 is a three-phase inverter connected between the power supply 100 and the load 300, converts DC power supplied from the power supply 100 into AC power, and supplies the AC power to the load 300. As shown in FIG. 31, the power conversion device 200 includes a main conversion circuit 201 that converts DC power into AC power and outputs the AC power, a drive circuit 202 that outputs a drive signal for driving each switching element of the main conversion circuit 201, and a control circuit 203 that outputs a control signal for controlling the drive circuit 202 to the drive circuit 202.

The load 300 is a three-phase electric motor driven by the AC power supplied from the power conversion device 200. Note that the load 300 is not limited for a specific use, and is an electric motor mounted on various electric devices, and is used as an electric motor for a hybrid vehicle, an electric vehicle, a railroad vehicle, an elevator, or an air conditioner, for example.

The power conversion device 200 will be described in detail below. The main conversion circuit 201 includes switching elements and freewheeling diodes (not shown), and converts DC power supplied from the power supply 100 into AC power by switching of the switching elements, and supplies the AC power to the load 300. Although there are various specific circuit configurations of the main conversion circuit 201, the main conversion circuit 201 according to the present embodiment is a two-level three-phase full-bridge circuit, and can be configured with six switching elements and six freewheeling diodes that are connected in anti-parallel to the respective switching elements. The semiconductor device according to any one of Embodiment 1 to Embodiment 5 is applied to each switching element of the main conversion circuit 201. The six switching elements are connected in series for every two switching elements to constitute upper and lower arms, and the upper and lower arms constitute one of phases (U phase, V phase, and W phase) of the full-bridge circuit. The output terminals of these upper and lower arms, that is, the three output terminals of the main conversion circuit 201 are connected to the load 300.

In order to increase the current that can be processed by the power conversion device 200, the main conversion circuit 201 includes a plurality of the switching elements, in other words, a plurality of the semiconductor devices, and the switching devices can be connected in parallel in the main conversion circuit 201. Here, when a semiconductor device including the surge current conduction region 301 is used for a plurality of, preferably all, switching elements, even if a surge current flows in the power conversion device 200, the pn diodes do not operate in some of or all of the switching elements, and the current can be prevented from concentrating on a small number of switching elements. As the switching element, the MOSFET with the built-in SBD that serves as a freewheeling diode may be used.

The drive circuit 202 generates a drive signal for driving the switching elements of the main conversion circuit 201 and supplies the drive signal to control electrodes of the switching elements of the main conversion circuit 201. Specifically, in accordance with the control signal from the control circuit 203 to be described later, a drive signal for turning on a switching element or a drive signal for turning off a switching element is output to a control electrode of each switching element. When the switching element is maintained in the on-state, the drive signal is a voltage signal (on-signal) equal to or higher than the threshold voltage of the switching element, and when the switching element is maintained in the off-state, the drive signal is a voltage signal (off-signal) equal to or lower than the threshold voltage of the switching element.

The control circuit 203 controls the switching elements of the main conversion circuit 201 so that desired power is supplied to the load 300. Specifically, the time (on-time) during which each switching element of the main conversion circuit 201 is to be in the on-state is calculated on the basis of the power to be supplied to the load 300. For example, the main conversion circuit 201 can be controlled by PWM control for modulating the on-time of a switching element in accordance with the voltage to be output. Then, the control circuit outputs a control command (control signal) to the drive circuit 202 so that an on-signal is output to a switching element that should be in the on-state at each time point and an off-signal is output to a switching element that should be in the off-state at each time point. The drive circuit 202 outputs the on-signal or the off-signal as the drive signal to the control electrode of each switching element in accordance with the control signal.

In addition, when a freewheeling current flows through each switching element in the reverse direction, the control circuit 203 turns on the gate except for a short dead time. In other words, when the freewheeling current flows through the semiconductor device, a control signal for applying an on-voltage to the gate electrode 60 included in the semiconductor device is output. Thus, the unipolar current can be passed through the channel in the surge current conduction region 301, and heat generation can be prevented from concentrating on the surge current conduction region 301.

In the power conversion device 200 according to the present embodiment, the semiconductor device according to Embodiment 1 to Embodiment 5 is applied as the switching element of the main conversion circuit 201, and thus it is possible to implement the power conversion device 200 with low loss and high reliability of high-speed switching.

In the present embodiment, an example in which the present disclosure is applied to a two-level three-phase inverter has been described, but the present disclosure is not limited thereto and can be applied to various power conversion devices 200. In the present embodiment, the power conversion device 200 is the two-level power conversion device, but the power conversion device 200 may be a three-level or multi-level power conversion device, and the present disclosure may be applied to a single-phase inverter when power is supplied to a single-phase load. In addition, when power is supplied to a DC load or the like, the present disclosure can be also applied to a DC/DC converter or an AC/DC converter.

The power conversion device 200 to which the present disclosure is applied is not limited to the case where the load 300 is the electric motor, and can be used as a power supply device for an electric discharge machine, a laser processing machine, an induction heating cooker, or a contactless power supply system, and can be further used as a power conditioner for a solar power generation system, a power storage system, or the like.

In the semiconductor devices according to Embodiment 1 to Embodiment 5, aluminum (Al) is used as the p-type impurity. However, the p-type impurity may be boron (B) or gallium (Ga). The n-type impurity may be phosphorus (P) instead of nitrogen (N). The gate insulating film 50 may not be an oxide film such as SiO₂, and may be an insulating film other than an oxide film or a combination of an insulating film other than an oxide film and an oxide film. Further, although silicon oxide obtained by thermally oxidizing silicon carbide is used as the gate insulating film 50, silicon oxide of a deposited film by a CVD method may be used. In addition, the crystal structure, the plane orientation of the main surface, the off angle, the implantation conditions, and the like have been described using specific examples, but the application ranges are not limited to these numerical ranges.

Further, the semiconductor device may be a MOSFET having a super junction structure in which an SBD is built in.

### Variations of Embodiments Described Above

In the embodiments described above, the quality of material, material, size, shape, relative arrangement relationship, or implementation conditions of each component are described, but these are merely examples in all aspects and are not limited thereto.

Therefore, innumerable variations and equivalents not exemplified are conceivable within the scope of the technology disclosed in the present specification. For example, the present disclosure includes a case where at least one component is modified, added, or omitted, and a case where at least one component in at least one embodiment is extracted and combined with a component in another embodiment.

In at least one of embodiments described above, when a material name or the like is described without being particularly specified, the material includes other additives, for example, an alloy, unless contradiction occurs.

Further, unless contradiction occurs, when it is described that a component is provided in the above-described embodiments, “one or more” components may be provided.

Furthermore, each component in the embodiments described above is a conceptual unit, and the scope of the technology disclosed in the present specification includes a case where one component is formed of a plurality of structures, a case where one component corresponds to a part of a structure, and a case where a plurality of components are provided in one structure.

Further, each component in the embodiments described above includes a structure having another structure or a shape as long as the same function is exhibited.

In addition, the description in the present specification is referred to for all purposes related to the present technology and is not an admission that any is prior art.

### Description of Symbols

10: semiconductor substrate, 20: drift layer, 21: first separation region, 22: second separation region, 30: first well region, 31: second well region, 32: first protection region, 33: second protection region, 35: contact region, 36: first connection region, 37: second connection region, 38: JTE region, 40: source region, 45: silicon carbide conductive layer, 50: gate insulating film, 51: field insulating film, 52: protective insulating film, 55: interlayer insulating film, 60: gate electrode, 70: ohmic electrode, 71: Schottky electrode, 72: termination portion ohmic electrode, 80: source electrode, 81: gate pad, 82: gate wire, 84: drain electrode, 90: active region contact hole, 90A: active region first contact hole, 90B: active region second contact hole, 91: termination region contact hole, 95: gate contact hole, 99: resist mask, 100: power supply, 200: power conversion device, 201: main conversion circuit, 202: drive circuit, 203: control circuit, 300: load, 301: surge current conduction region, 302: auxiliary region, 303: hole filling auxiliary region, GT: gate trench, ST: Schottky trench

1.-18. (canceled)

19. A semiconductor device comprising:
a drift layer of a first conductivity type;
a gate electrode provided so as to face a well region of a second conductivity type and a source region of the first conductivity type via a gate insulating film;
a source electrode that is provided on an interlayer insulating film provided so as to cover the gate electrode and that is connected to the well region and the source region;
first separation regions of the first conductivity type provided in an active region having regions in which a plurality of MOSFETs each including the well region, the source region, and the gate electrode are arranged in the drift layer, the first separation region being provided to be connected to the drift layer and forming Schottky connection with the source electrode; and
at least one surge current conduction region provided in the active region that is the plurality of arranged regions or that is outside the plurality of arranged regions, and having a region for blocking connection between the source electrode and the drift layer, wherein a separation distance between two of the first separation regions that are each provided adjacent on one end side and the other end side of the surge current conduction region is larger than a separation distance between two of the first separation regions that are adjacent to each other in the active region outside the surge current conduction region.

20. The semiconductor device according to claim 19, wherein the surge current conduction region is formed over a region larger than a first width of the well region in a plan view.

21. The semiconductor device according to claim 19, wherein the at least one surge current conduction region is provided at a position covered with the source electrode in a plan view.

22. The semiconductor device according to claim 19, wherein any of the first separation regions is not formed in the at least one surge current conduction region.

23. The semiconductor device according to claim 19, wherein a total area of the at least one surge current conduction region in a plan view is 10% or less of an entire area of the semiconductor device in a plan view.

24. The semiconductor device according to claim 19, wherein the at least one surge current comprises a plurality of surge current conduction regions that are formed, and a separation distance between any two of the surge current conduction regions is 10 times or more the separation distance between two of the first separation regions that are each provided adjacent on one end side and the other end side of one of the surge current conduction regions.

25. The semiconductor device according to claim 19, wherein a plurality of the surge current conduction regions are formed, and the surge current conduction regions are provided periodically or at equal intervals in at least one direction of the semiconductor device in a plan view.

26. The semiconductor device according to claim 19, wherein the gate electrode is continuously formed inside and outside the at least one surge current conduction region in a plan view.

27. The semiconductor device according to claim 19, wherein the gate electrode is not provided in the at least one surge current conduction region in a plan view.

28. The semiconductor device according to claim 19, wherein the at least one surge current conduction region is a region blocking connection between the source electrode and the drift layer and includes at least one auxiliary region of the second conductivity type having a second width larger than the first width.

29. The semiconductor device according to claim 28, wherein the at least one auxiliary region isolates the source electrode and the drift layer in a second contact hole penetrating the interlayer insulating film.

30. The semiconductor device according to claim 28, wherein the source electrode is connected to the well region, the source region, and the first separation regions via a first contact hole penetrating the interlayer insulating film, is connected to the at least one auxiliary region via the second contact hole penetrating the interlayer insulating film, and is not connected to the drift layer.

31. The semiconductor device according to claim 28, wherein the at least one surge current conduction region further includes a second separation region of the first conductivity type that is adjacent to the auxiliary region or the well region, connected to the drift layer, and opposite to the gate electrode via the gate insulating film, and the source region is provided in a surface layer portion of the at least one auxiliary region on which the gate insulating film and the gate electrode are formed.

32. The semiconductor device according to claim 28, wherein the at least one surge current conduction region does not include a second separation region of the first conductivity type that is adjacent to the auxiliary region or the well region, connected to the drift layer, and opposite to the gate electrode via the gate insulating film.

33. The semiconductor device according to claim 19, further comprising a contact region formed in a surface layer portion of the well region, having an impurity concentration of the second conductivity type higher than an impurity concentration of the second conductivity type of the well region, and connected to the source electrode.

34. A power conversion device comprising:
a main conversion circuit that includes a semiconductor device according to claim 19, converts input power, and outputs the converted power, and
a control circuit to output a control signal for controlling the main conversion circuit.

35. The power conversion device according to claim 34, wherein the control circuit outputs the control signal for applying an on-voltage to the gate electrode included in the semiconductor device when a freewheeling current flows in the semiconductor device.

36. The power conversion device according to claim 34, wherein the main conversion circuit includes a plurality of the semiconductor devices, and a plurality of the semiconductor devices are connected in parallel to each other.

37. The power conversion device according to claim 34, wherein all switching elements connected in parallel in the main conversion circuit each use the semiconductor device.
